(19) United States
(12) Patent Application Publication
(10) Pub. No.: US 2026/0090160 A1
(43) Pub. Date: Mar. 26, 2026

(54) LIGHT-TRANSMITTAL PRESSING PLATE, PRESSURIZING ASSEMBLY, HEATING AND PRESSURIZING DEVICE AND LIGHT-EMITTING CHIP TRANSFER APPARATUS

(71) Applicants: Beijing BOE Technology Development Co., Ltd., Daxing District (CN); BOE TECHNOLOGY GROUP CO., LTD, Beijing (CN)

(72) Inventors: Kang CAO, Beijing (CN); Zhonglin CHEN, Beijing (CN); Ze REN, Beijing (CN); Junwei YAN, Beijing (CN)

(21) Appl. No.: 19/112,914

(22) PCT Filed: Sep. 25, 2023
(86) PCT No.: PCT/CN2023/121227

§ 371 Date: Mar. 18, 2025

(30) Foreign Application Priority Data
May 30, 2023 (CN) 202310628821.9

(51) Int. Cl. H10H 29/03; B65G 47/91

(52) U.S. Cl. CPC H10H 29/03; B65G 47/91

(57) ABSTRACT

A light-transmitting pressing plate comprises a first surface and a second surface in parallel to each other, and the light-transmitting pressing plate allows a laser of a target wavelength to be transmitted in a first direction from the first surface to the second surface. Under the action of pressure and the laser of the target wavelength, the light-transmitting pressing plate is used for transferring light-emitting chips on a first substrate to a second substrate, the first substrate being located on one side close to the second surface of the light-transmitting pressing plate and allowing the laser of the target wavelength to be transmitted in the first direction, and the first substrate being closer to the light-transmitting pressing plate than the second substrate. In the present disclosure, the light-transmitting pressing plate provides a basis for pressurizing and laser irradiation, thus achieving the feasibility of mass transfer of light-emitting chips.

### CROSS-REFERENCE TO RELATED APPLICATION

The present disclosure claims priority to Chinese Patent Application No. 202310628821.9, filed on May 30, 2023 and titled “Heating and Pressurizing Device and Chip Transfer Apparatus”, the entire content of which is incorporated herein by reference in its entirety.

### TECHNICAL FIELD

The present disclosure relates to the field of display technology and particularly to a light-transmitting pressing plate, a pressurizing assembly, a heating and pressurizing device, and a light-emitting chip transfer apparatus.

### BACKGROUND

Mass transfer is a manufacturing technology that precisely transfers millions or even tens of millions of micrometer-scale light-emitting chips from a source electrode plate to a drive substrate, and there are many challenges in terms of transfer yield, precision, and speed, which cause a technical bottleneck hindering new-generation display products. At present, a variety of laser-assisted transfer technologies have been developed, which have advantages of small damage to devices, high selectivity, fast and efficient response, and have become a highly promising solution for mass transfer.

The mass transfer process is very demanding, and requires high temperature, high pressure, high-precision bonding of upper and lower substrates of different sizes, laser scanning processing, and peeling of the upper and lower substrates. This process is very important in production of display products. Due to the process complexity in the current technology, there is an urgent need for a simpler transfer technology that can ensure transfer yield, precision, and speed.

It should be noted that the information disclosed in the Background is only used to enhance understanding of the background of the present disclosure, and therefore it may include information that does not constitute existing technology already known to those skilled in the art.

### SUMMARY

An objective of the present disclosure is to provide a heating and pressurizing device that integrates heating, pressurization, and laser irradiation functions and provides feasibility for mass transfer of chips.

To achieve the above objective, the present disclosure adopts following technical solutions.

According to a first aspect of the present disclosure, there is provided with a light-transmitting pressing plate, including a first surface and a second surface parallel to each other, each of the first surface and the second surface extending along a plane. The light-transmitting pressing plate allows a laser of a target wavelength to be transmitted in a first direction from the first surface to the second surface;

the light-transmitting pressing plate is configured to transfer a light-emitting chip arranged on a first substrate to a second substrate under action of pressure and under action of the laser of the target wavelength; the first substrate is on one side of the light-transmitting pressing plate close to the second surface and allows a laser of a target wavelength to be transmitted in a first direction; the first substrate and the second substrate are on the same side of the light-transmitting pressing plate, and the first substrate is closer to the light-transmitting pressing plate than the second substrate.

In an exemplary embodiment of the present disclosure, a refractive index of the light-transmitting pressing plate for a laser with a wavelength of 355 nm is greater than 1 and less than 1.6.

In an exemplary embodiment of the present disclosure, a distance between the first surface and the second surface is greater than or equal to 8 mm and less than or equal to 35 mm.

In an exemplary embodiment of the present disclosure, an offset of a light spot is less than or equal to 0.5 mm after the light-transmitting pressing plate transmits a laser with an incident angle in a range of less than or equal to 14 degrees.

In an exemplary embodiment of the present disclosure, degradation of uniformity of a laser light spot does not exceed 2% after the light-transmitting pressing plate transmits laser within an A mm×B mm laser field, wherein A and B are both less than or equal to 70.

In an exemplary embodiment of the present disclosure, uniformity of a laser light spot after the light-transmitting pressing plate transmits a laser with an incident angle in a range of less than or equal to 14 degrees is equivalent to or superior to uniformity of the laser light spot before incidence.

In an exemplary embodiment of the present disclosure, a material of the light-transmitting pressing plate includes fused quartz glass or synthetic quartz glass.

In an exemplary embodiment of the present disclosure, the quartz glass internally contains a content, and a particle size of the content is less than 0.1 mm.

In an exemplary embodiment of the present disclosure, the light-transmitting pressing plate includes a light-transmitting region and a peripheral region, the peripheral region surrounding the light-transmitting region,

a first gas passage is provided in the peripheral region, and the first gas passage has a first adsorption port extending to the second surface and distributed around the light-transmitting region.

In an exemplary embodiment of the present disclosure, the light-transmitting pressing plate includes a contour surface between the first surface and the second surface;

the first gas passage includes a ring-shaped groove and a vent hole; an opening of the ring-shaped groove is on the second surface and forms the first adsorption port; one end of the vent hole is in communication with the ring-shaped groove, and another end of the vent hole is on the contour surface and forms a first gas extraction port; the first gas extraction port is configured to be in communication with a gas extraction device.

In an exemplary embodiment of the present disclosure, an outer contour of the light-transmitting pressing plate is rectangular;

the light-transmitting pressing plate includes four sub-contour surfaces between the first surface and the second surface, and the first gas passage includes four gas channels and four groups of ventilation holes, the four sub-contour surfaces, the four gas channels, and the four groups of ventilation holes being in one-to-one correspondence;

one gas channel of the four gas channels is located between one corresponding sub-contour surface of the four sub-contour surfaces and the light-transmitting region, and one end of one group of ventilation holes of the four groups of ventilation holes is in communication with one corresponding gas channel of the four gas channels, while the other end of one group of ventilation holes of the four groups of ventilation holes is located on the second surface and forms the first adsorption port;

one gas channel of the four gas channels extends to two sub-contour surfaces adjacent to one corresponding sub-contour surface of the four sub-contour surfaces, and a pair of mouths are formed on the adjacent two sub-contour surfaces of the four sub-contour surfaces; at least one mouth of four pairs of mouths forms a first gas extraction port and is configured to be in communication with a gas extraction device, while remaining mouths of the of four pairs of mouths are sealed.

In an exemplary embodiment of the present disclosure, the four gas channels are in communication with each other, and one of the four pairs of mouths forms the first gas extraction port.

According to a second aspect of the present disclosure, there is provided with a pressurizing assembly, including a connecting portion and the light-transmitting pressing plate according to the above aspect;

the connecting portion has a through hollow region, and the connecting portion is fixedly connected to the light-transmitting pressing plate and is located on one side close to the first surface of the light-transmitting pressing plate;

in the first direction, there is an overlapping region between a light-transmitting region of the light-transmitting pressing plate and the hollow region.

In an exemplary embodiment of the present disclosure, the pressurizing assembly further includes a metal frame and an elastic pad that are located between the connecting portion and the light-transmitting pressing plate;

the metal frame is located between the elastic pad and the light-transmitting pressing plate; each of the metal frame and the elastic pad has a ring-shaped structure; orthographic projections of the metal frame and the elastic pad on the light-transmitting pressing plate surround the light-transmitting region.

According to a third aspect of the present disclosure, there is provided with a heating and pressurizing device, including a heating carrying mechanism and a pressurizing driving mechanism,
the heating carrying mechanism includes a heating member and a carrying platform, the carrying platform is configured to carry a second substrate, and the heating member is configured to heat the second substrate on the carrying platform;
the pressurizing driving mechanism includes a driving mechanism and the pressurizing assembly according to the above aspect, the driving mechanism being connected to the pressurizing assembly;
the light-transmitting pressing plate and the carrying platform are arranged opposite to each other in the first direction; the light-transmitting pressing plate is configured to connect a first substrate; and the driving mechanism is configured to drive the light-transmitting pressing plate to move in the first direction, to allow the light-transmitting pressing plate to bring the first substrate into contact with the second substrate in the first direction and generate interaction force.

In an exemplary embodiment of the present disclosure, the driving mechanism includes:
a first slide rail extending along the first direction;
a slide head assembly slidably connected to the first slide rail, the slide head assembly being connected to the pressurizing assembly; and
a power driving member connected to the slide head assembly and configured to drive the slide head assembly to slide along the first slide rail and apply force to the pressurizing assembly.

In an exemplary embodiment of the present disclosure, a second gas passage is provided inside the carrying platform, and the second gas passage has a second adsorption port extending to a surface of the carrying platform facing one side of the pressurizing assembly.

In an exemplary embodiment of the present disclosure, there are two pressurizing driving mechanisms; the two pressurizing driving mechanisms are respectively located on both sides of the heating member in a second direction; the two pressurizing driving mechanisms are symmetrically arranged about a central axis of the heating member; and the second direction is perpendicular to the first direction.

In an exemplary embodiment of the present disclosure, the target wavelength is greater than or equal to 100 nm and less than or equal to 2000 nm.

According to a fourth aspect of the present disclosure, there is provided with a light-emitting chip transfer apparatus, including:
the heating and pressurizing device according to the above aspect; and
a laser irradiation device configured to generate a laser of a target wavelength and irradiate the laser onto a light-transmitting region of the light-transmitting pressing plate.

According to a fifth aspect of the present disclosure, there is provided with a light-emitting chip transfer method, including:
transferring a light-emitting chip from a source substrate to an intermediate substrate, and then from the intermediate substrate to a display substrate,
the light-emitting chip transfer apparatus according to the above aspect is configured to transfer the light-emitting chip from the source substrate to the intermediate substrate, the first substrate being the source substrate and the second substrate being the intermediate substrate; and/or
the light-emitting chip transfer apparatus according to the above aspect is configured to transfer the light-emitting chip from the intermediate substrate to the display substrate, the first substrate being the intermediate substrate and the second substrate being the display substrate.

According to a sixth aspect of the present disclosure, there is provided with a light-emitting chip transfer method, including:
heating, pressurizing and laser-irradiating a first substrate and a second substrate located on a heating and pressurizing device by using the light-emitting chip transfer apparatus according to the above aspect, wherein the first substrate allows a laser of a target wavelength to be transmitted in a first direction, and the light-emitting chip is initially located on the first substrate,
the driving mechanism drives the pressurizing assembly to move and pressurize in a direction towards the carrying platform, to allow the first substrate and the second substrate to come into contact and generate interaction force;
the heating member heats the second substrate carried on the carrying platform;
the laser generated by the laser irradiation device passes through a light-transmitting region of the light-transmitting pressing plate to laser-irradiate the first substrate and the second substrate, and the light-emitting chip on the first substrate is transferred to the second substrate.

In the embodiments of the present disclosure, the feasibility of pressure bearing is achieved by the light-transmitting pressing plate, and since the light-transmitting pressing plate may transmit the laser of the target wavelength in the first direction, the feasibility of laser irradiation is realized, which achieves the feasibility of integrating pressurization and laser irradiation, simplifies the process of mass transfer of the light-emitting chips, and improves the production efficiency.

### BRIEF DESCRIPTION OF THE DRAWINGS

The above and other features and advantages of the present disclosure will become more apparent by describing in detail exemplary embodiments with reference to the accompanying drawings.

FIG. 1 is a schematic view of a heating and pressurizing device in an exemplary embodiment of the present disclosure.

FIG. 2 is a schematic view of a pressurizing assembly in an exemplary embodiment of the present disclosure.

FIG. 3 is a schematic view of some members of a heating and pressurizing device in an exemplary embodiment of the present disclosure.

FIG. 4 is a schematic view of a power output end of a power conversion element of a heating and pressurizing device in an exemplary embodiment of the present disclosure.

FIG. 5 is a schematic view of a connecting portion in an exemplary embodiment of the present disclosure.

FIG. 6 is a side view of a pressurizing assembly in an exemplary embodiment of the present disclosure.

FIG. 7 is an exploded view of fixation of a pressurizing assembly in an exemplary embodiment of the present disclosure.

FIG. 8 is an exploded view of fixation of another pressurizing assembly in an exemplary embodiment of the present disclosure.

FIG. 9 is a schematic view of a light-transmitting pressing plate in an exemplary embodiment of the present disclosure.

FIG. 10 is a schematic view of refraction of a laser through a light-transmitting pressing plate in an exemplary embodiment of the present disclosure.

FIG. 11 is a schematic view of another light-transmitting pressing plate in an exemplary embodiment of the present disclosure.

FIG. 12 is a bottom view of another light-transmitting pressing plate in an exemplary embodiment of the present disclosure.

FIG. 13 is a side view of another light-transmitting pressing plate in an exemplary embodiment of the present disclosure.

FIG. 14 is a bottom view of a light-transmitting pressing plate in an exemplary embodiment of the present disclosure.

### REFERENCE NUMERALS

Z—first direction; X—second direction; Y—third direction;
10—heating carrying mechanism; 20—pressurizing driving mechanism; 30—base; 40—base leveling member; 50—reinforcement member;
100—heating member; 200—carrying platform; 500—second support member;
210—second adsorption port; 220—second gas extraction port;
300—pressurizing assembly; 400—driving mechanism;
310—connecting portion; 320—light-transmitting pressing plate; 330—metal frame; 340—elastic pad; 350—first fixing bolt; 360—second fixing bolt; 370—third fixing bolt; 380—straight-through joint; 390—fourth fixing bolt; 308—washer; 309—locking nut;
311—hollow region; 312—pressurizing region;
AA—light-transmitting region; BB—peripheral region;
321—second surface; 322—first gas extraction port; 323—first adsorption port; 324—ring-shaped groove; 325—ventilation hole; 326—contour surface; 327—vent hole; 328—gas channel;
3261—sub-contour surface;
410—first support member; 420—first slide rail; 430—slide head assembly; 440—power driving member; 450—photoelectric sensor; 460—sensor limiting piece; 470—second slide rail;
431—slide block; 432—first connector; 433—second connector; 434—guide shaft; 435—pressure sensor; 436—limiting portion; 437—linear bearing;
4321—first connecting sub-block; 4322—second connecting sub-block; 22a—first connecting arm; 22b—second connecting arm;
441—drive motor; 442—power conversion element; 4421—power output end; 443—speed reducer; 451—limit slot.

### DETAILED DESCRIPTION

Exemplary embodiments will be described more fully with reference to the accompanying drawings. However, the exemplary embodiments may be embodied in a variety of forms and should not be construed as being limited to the embodiments set forth herein. Instead, these embodiments are provided so that the present disclosure will be thorough and complete, and the concepts of the exemplary embodiments will be fully given to those skilled in the art. Features, structures, or characteristics described herein may be combined in any suitable manner in one or more embodiments. In the following description, many specific details are provided for a thorough understanding of the embodiments of the present disclosure.

In the drawings, thicknesses of regions and layers may be exaggerated for sake of clarity. Same reference numbers denote the same or similar structures in the figures, and thus the detailed description thereof will be omitted.

The features, structures or characteristics described herein may be combined in one or more embodiments in any suitable manner. In the following description, numerous specific details are provided to fully understand the embodiments of the present disclosure. However, those skilled in the art will recognize that the technical solutions of the present disclosure may be practiced without one or more of the specific details, or other components, steps and so on may be used. In other cases, the well-known technical solutions are not shown or described in detail to avoid obscuring various aspects of the present disclosure.

When a structure is described as “above” another structure, it probably means that the structure is integrally formed on another structure, or the structure is “directly” disposed on another structure, or the structure is “indirectly” disposed on another structure through an additional structure.

Terms such as “one,” “an/a,” and “said” are used herein to indicate the presence of one or more elements/component parts/and others. Terms “including” and “having” have an inclusive meaning which means that there may be additional elements/component parts/and others in addition to the listed elements/component parts/and others. Terms such as “first” and “second” are used herein only as markers, and they do not limit the number of objects modified after them.

The mass transfer process is very demanding. In order to achieve mass transfer of light-emitting chips in the related art, two substrates to be transferred are first pressurized in a pressurization chamber, so that massive light-emitting chips arranged on the first substrate may be fixed on the second substrate; then, the two substrates to be transferred are irradiated with laser in a laser chamber to dissociate the first substrate from the massive light-emitting chips; afterwards, the two substrates to be transferred are separated. The multi-chamber operation not only increases the process complexity of transferring light-emitting chips, but also greatly lowers the production efficiency due to the transfer between multiple chambers.

The present disclosure provides a light-emitting chip transfer apparatus, including a heating and pressurizing device and a laser irradiation device. The laser irradiation device is used to generate a laser of a target wavelength.

The light-emitting chip transfer apparatus may be used to complete the mass transfer of light-emitting chips (such as Micro LED chips), i.e., precisely transfer millions or even tens of millions of micrometer-scale light-emitting chips from the first substrate to the second substrate. The first substrate may be a source substrate (e.g., wafer sapphire), and the second substrate may be a glass substrate. Alternatively, the first substrate may be a glass substrate, and the second substrate may be a display substrate containing a drive circuit (for driving the light-emitting chips to emit light).

For the heating and pressurizing device and the laser irradiation device included in the light-emitting chip transfer apparatus, the heating and pressurizing device is used to achieve contact and generate interaction force between the first substrate and the second substrate, as well as to heat the second substrate. The laser irradiation device is used to generate laser of the target wavelength to laser-irradiate the first substrate after the first substrate and the second substrate come into contact and generate interaction force therebetween. In this way, with the cooperation of the heating and pressurizing device and the laser irradiation device, an integrated operation of transferring the light-emitting chips arranged on the first substrate to the second substrate may be achieved, thereby simplifying the operation process of mass transfer of light-emitting chips and improving the production efficiency.

The laser of the target wavelength generated by the laser irradiation device may pass through the first substrate to effectively peel off or dissociate massive light-emitting chips from the first substrate. The wavelength of the laser generated by the laser irradiation device may be greater than or equal to 100 nm and less than or equal to 2000 nm. Certainly, the wavelength of the laser generated by the laser irradiation device may also be slightly less than 100 nm or slightly greater than 2000 nm, as long as it may achieve the peel-off or dissociation of the light-emitting chips from the first substrate.

For example, a wavelength range of the laser generated by the laser irradiation device may be within a range of 390 nm-780 nm, such as visible light; or within a range of 780 nm-2000 nm, such as infrared light; or within a range of 100 nm-390 nm, such as ultraviolet light. Specifically, the wavelength of the laser generated by the laser irradiation device may be within one of the following ranges: 770 nm˜622 nm (red light), 622 nm˜597 nm (orange light), 597 nm˜577 nm (yellow light), 577 nm˜492 nm (green light), 492 nm˜450 nm (cyan light), 450 nm˜435 nm (blue light), 455 nm˜350 nm (purple light). More specifically, the wavelength of the laser generated by the laser irradiation device is 355 nm.

The heating and pressurizing device may realize the contact and interaction force between the first substrate and the second substrate through a pressurizing operation, and may also achieve adhesion and fixation of massive light-emitting chips on the first substrate with the second substrate through a heating operation. When the laser of the target wavelength generated by the laser irradiation device is irradiated onto the first substrate, the light-emitting chips may be peeled off from the first substrate (the first substrate is a source substrate while the second substrate is an intermediate substrate) or dissociated from the first substrate (the first substrate is an intermediate substrate while the second substrate is a display substrate).

For the heating and pressurizing device, for example, the second substrate may be heated to 150° C., and a pressure intensity of 0.5 MPa may be generated between the first substrate and the second substrate, which last for 10 minutes to ensure the stability of adhesion of the light-emitting chips on the first substrate with the second substrate.

The laser generated by the laser irradiation device may be shaped in advance, to make a light spot shape of the laser identical to a contour shape of the light-emitting chip, and ensure the uniformity of energy in a light spot region. For example, the contour shape of the light-emitting chip is rectangular, and in this case, the light spot of the laser may be shaped so that it is a rectangular flat-top light spot. In addition, the laser irradiation device may irradiate the first substrate by matrix dotting, and the dotted matrix corresponds to the arrangement of the light-emitting chips on the first substrate; one dotting site may be corresponding to one light-emitting chip, or one dotting site may be corresponding to 2*2 light-emitting chips, or 2*3 light-emitting chips, and so on.

It should be noted that the second substrate has a colloid that may achieve adhesive bonding under heating conditions, to ensure adhesion and fixation of the light-emitting chips on the first substrate with the second substrate after the first substrate comes into contact with the second substrate and generates the interaction force therebetween and the second substrate is heated. For a situation where the light-emitting chips are dissociated from the first substrate, the light-emitting chips are fixed on the first substrate by a dissociating adhesive, so that the dissociating adhesive may be induced to lose adhesiveness after laser irradiation, so as to achieve dissociation of the light-emitting chips.

The heating and pressurizing device included in the light-emitting chip transfer apparatus will be explained in detail below.

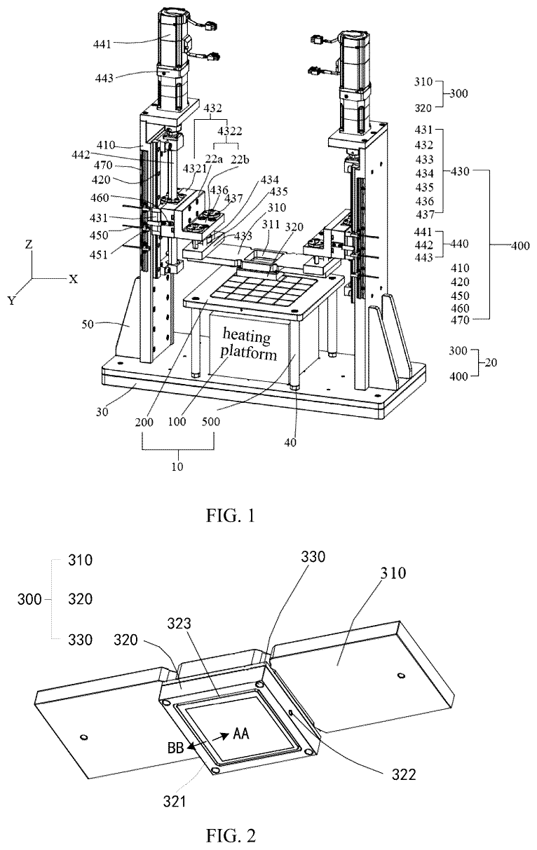

FIG. 1 illustrates a schematic view of a heating and pressurizing device according to the present disclosure, and FIG. 2 illustrates a schematic view of a pressurizing assembly according to the present disclosure. As shown in FIGS. 1 and 2, the heating and pressurizing device includes: a heating carrying mechanism 10 configured to carry the second substrate and heat the second substrate; and a pressurizing driving mechanism 20 including a driving mechanism 400 and a pressurizing assembly 300 connected to the driving mechanism 400. The pressurizing assembly 300 includes a light-transmitting pressing plate 320 arranged opposite to the heating carrying mechanism 10 in a first direction. The light-transmitting pressing plate 320 is configured to connect the first substrate, and the driving mechanism 400 is configured to drive the light-transmitting pressing plate 320 to move towards the heating carrying mechanism 10, so as to bring the first substrate into contact with the second substrate and generate interaction force.

For the heating and pressurizing device according to the present disclosure, the second substrate is carried by the heating carrying mechanism 10, and the first substrate is connected by the light-transmitting pressing plate 320. Afterwards, the second substrate may be heated by the heating carrying mechanism 10, and when the driving mechanism 400 drives the light-transmitting pressing plate 320 included in the pressurizing assembly 300 to move towards the heating carrying mechanism 10, the first substrate is brought into contact with the second substrate and the interaction force is generated, thereby achieving the adhesion and fixation of the light-emitting chips arranged on the first substrate with the second substrate. Additionally, combined with the transmittance of the light-transmitting pressing plate 320, the feasibility of laser irradiation on the first substrate is achieved, so that the heating and pressurizing device may integrate heating, pressurization, and laser irradiation functions and provide feasibility for mass transfer of the light-transmitting chips.

For example, the heating carrying mechanism 10 maintains a heating temperature of the second substrate at 150° C., and the driving mechanism 400 drives the first substrate to come into contact with the second substrate, generating a pressure intensity of 0.5 MPa between the first substrate and the second substrate, which last for 10 minutes to ensure the stability of adhesion of the light-emitting chips on the first substrate with the second substrate.

Optionally, as shown in FIG. 1, the heating carrying mechanism 10 includes a carrying platform 200 and a heating member 100, and the carrying platform 200 is arranged on one side of the heating member 100 in a first direction Z.

The first direction Z may be a vertical direction, and for example, the carrying platform 200 is arranged above the heating member 100 along the vertical direction.

The carrying platform 200 and the light-transmitting pressing plate 320 are arranged opposite to each other in the first direction Z (i.e., there is an overlapping region). The carrying platform 200 is used to carry and fix the second substrate, so that when the driving mechanism 400 drives the light-transmitting pressing plate 320 to move along the first direction Z towards the carrying platform 200, the first substrate connected to the light-transmitting pressing plate 320 may come into contact with the second substrate on the carrying platform 200 and generate the interaction force. The heating member 100 has a heating function and is mainly used to heat the carrying platform 200 to achieve heating of the second substrate. The heating member 100 may be a heating platform and may include a housing and structures such as a heating tube and a temperature controller inside the housing, which will not be specifically limited in the present disclosure.

The carrying platform 200 and the heating platform may be connected as a whole. For example the carrying platform 200 is connected to a side surface of the heating platform in the first direction Z, or the carrying platform 200 and the heating platform are directly processed into an integrated structure. In addition, the carrying platform 200 may not be connected to the heating member 100, but may be supported on one side of the heating member 100 in the first direction Z by other support structures.

For example, as shown in FIG. 1, the heating carrying mechanism 10 further includes a second support member 500 located around the heating member 100 and supporting the carrying platform 200 on one side of the heating member 100 in the first direction Z. There may be a plurality of second support members 500 surrounding the heating member 100. The number of second support members 500 may be set according to the size or shape of the carrying platform 200.

The second support member 500 may be a support column that extends along the first direction Z. A cross-section of the support column may be circular, elliptical, triangular, rectangular, square, or other polygonal shapes, etc., which will not be specifically limited in the present disclosure.

For the number of second support members 500, for example, if the carrying platform 200 is approximately a circular platform, the number of second support members 500 may be three, four, five or more, and the plurality of second support members 500 are evenly distributed along a circumferential direction of the heating member 100. If the carrying platform 200 is approximately quadrilateral, the number of second support members 500 may be four, six, eight or more, and the plurality of second support members 500 may be distributed around the heating member 100 according to locations of the four sides of the carrying platform 200.

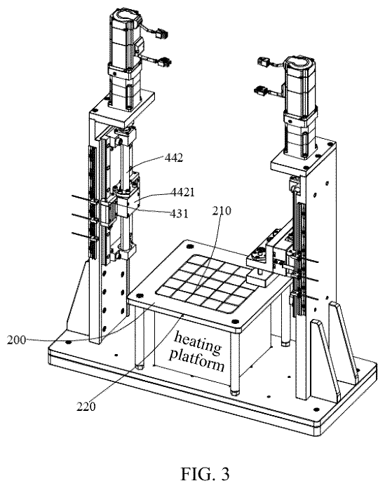

In some embodiments of the present disclosure, as shown in FIG. 3, the carrying platform 200 has an internal second gas passage (not shown in the figure), and the second gas passage has a second adsorption port 210 and a second gas extraction port 220. The second gas extraction port 220 is used to connect a gas extraction device, and the gas extraction device adsorbs and fixes the second substrate through the second adsorption port 210 of the second gas passage. The second adsorption port 210 is an opening of the second gas passage that extends to a surface of the carrying platform 200 facing the light-transmitting pressing plate 320. The second gas extraction port 220 is an opening of the second gas passage that extends to a surface of the carrying platform 200 facing away from the light-transmitting pressing plate 320, or extends to the surface of the carrying platform 200 facing the light-transmitting pressing plate 320, or extends to a side wall of the carrying platform 200.

In some embodiments of the present disclosure, as shown in FIG. 1, the driving mechanism 400 is on one side of the heating carrying mechanism 10 in a second direction X. When the driving mechanism 400 drives the light-transmitting pressing plate 320 to move along the first direction Z, it may be ensured that the light-transmitting pressing plate 320 generates a certain amount of interaction force between the first substrate and the second substrate, thereby ensuring extrusion intensity between the light-emitting chip on the first substrate and the second substrate, which in turn ensures adhesion strength between the light-emitting chip and the second substrate.

The second direction X is approximately perpendicular to the first direction Z; for example, the second direction X may be a horizontal direction. The number of driving mechanisms 400 may be two, three, or more; preferably, there are two driving mechanisms 400. Two driving mechanisms 400 are on both sides of the heating carrying mechanism 10 in the second direction X, and are symmetrically arranged to facilitate the driving mechanism 400 to apply pressure to the pressurizing assembly 300 from both ends of the pressurizing assembly 300 in the second direction X, which helps to maintain the stability and uniformity of the force applied to the pressurizing assembly 300.

In some embodiments of the present disclosure, as shown in FIG. 1, the driving mechanism 400 includes a first slide rail 420, a slide head assembly 430, and a power driving member 440. The first slide rail 420 extends along the first direction Z; the slide head assembly 430 is slidably connected to the first slide rail 420 and is connected to the pressurizing assembly 300; the power driving member 440 is connected to both the slide head assembly 430 and the pressurizing assembly 300 and is configured to drive the slide head assembly 430 to slide along the first slide rail 420 and apply force to the pressurizing assembly 300.

Optionally, the first slide rail 420 has two first rails arranged along a third direction Y, i.e., the two first rails are located on both side of the power driving member 440 in the third direction Y. The third direction Y may be perpendicular to both the first direction Z and the second direction X.

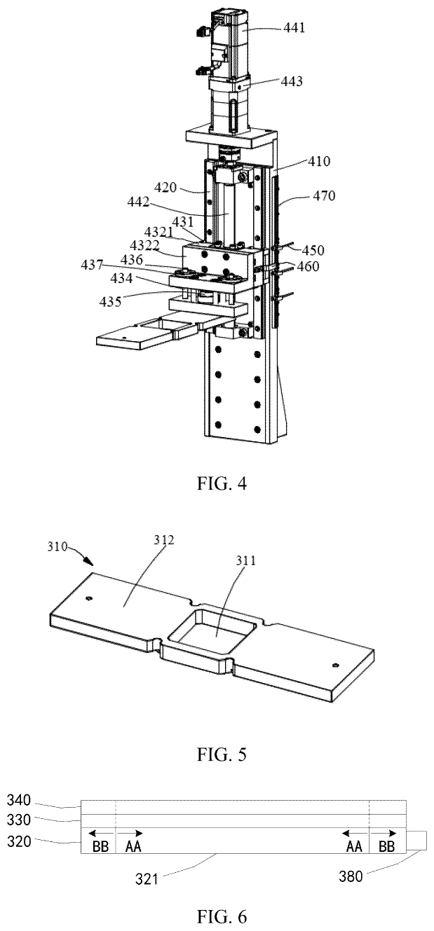

In some embodiments, as shown in FIGS. 1 and 4, the slide head assembly 430 includes a slide block 431 and a connecting member. The connecting member includes a first connector 432, a second connector 433, at least one guide shaft 434, and a pressure sensor 435. The slide block 431 is slidably connected to the first slide rail 420, and the power driving member 440 is used to drive the slide block 431 to slide along the first slide rail 420. The first connector 432 is connected to the slide block 431 or connected to the slide block 431 and the power driving member 440. The second connector 433 is located on one side of the first connector 432 close to the heating carrying mechanism 10 and is connected to the pressurizing assembly 300. At least one guide shaft 434 has one end slidably connected to the first connector 432 and another end fixedly connected to the second connector 433. At least one guide shaft 434 extends along the first direction Z. The pressure sensor 435 is located between the first connector 432 and the second connector 433.

In this way, the slide block 431 may be driven by the power driving member 440, to drive the first connector 432 to move along the guide shaft 434 towards the second connector 433, and then force is applied to the pressurizing assembly 300 through the second connector 433; the magnitude of the force may be detected by the pressure sensor 435.

The slide block 431 is slidably connected to one side of the first slide rail 420 close to the heating carrying mechanism 10, and is connected to a power output end 4421 of the power driving member 440, which may be direct connection or indirect connection through other components. In addition, for the slidable connection between the slide block 431 and the first slide rail 420, combined with the situation where the first slide rail 420 has two first rails as described above, the slide block 431 has a second rail that matches the shape and size of the first rails on the first slide rail 420. When the number of slide blocks 431 is two, each slide block 431 have one second rail; or when the number of slide blocks 431 is one, the slide block 431 has two second rails.

Optionally, the first connector 432 may be approximately an “L”-shaped connector. At this point, the first connector 432 may be an integral member or may include a plurality of subcomponents that satisfy a certain connection relationship therebetween. For example, in a specific embodiment, as shown in FIG. 1 or FIG. 4, the first connector 432 includes a first connecting sub-block 4321 and a second connecting sub-block 4322. The first connecting sub-block 4321 is connected to the slide block 431, or connected to the slide block 431 and the power output end 4421 of the power driving member 440. The second connecting sub-block 4322 is connected to the first connecting sub-block 4321 and at least one guide shaft 434, and at least one guide shaft 434 is slidably connected to the second connecting sub-block 4322.

The power driving member 440 may drive the first connecting sub-block 4321 to slide along the first slide rail 420 by driving the slide block 431, or may directly drive the first connecting sub-block 4321 to slide along the first slide rail 420. It should be noted that the first connecting sub-block 4321 may be a one-piece block structure. When there are a plurality of slide blocks 431 (such as two slide blocks 431), the first connecting sub-block 4321 may be connected to the two slide blocks 431 simultaneously to maintain balance when the slide blocks 431 are sliding.

As shown in FIG. 1, the second connecting sub-block 4322 includes a first connecting arm 22a and a second connecting arm 22b that are perpendicular to each other (L-shaped). The first connecting arm 22a is connected to the first connecting sub-block 4321, and at least one guide shaft 434 is slidably connected to the second connecting arm 22b. In this embodiment, the first connector 432 includes the first connecting sub-block 4321 and the second connecting sub-block 4322 separated from each other. This structural design helps to maintain the stability of the fit between the first slide rail 420 and the slide block 431 during device disassembly, and during disassembly, it is possible to disassemble the second connecting sub-block 4322 alone and meanwhile maintain a connection state of the first connecting sub-block 4321, the slide block 431, and the first slide rail 420, so as to avoid reducing the precision of the fit between the first slide rail 420 and the slide block 431 due to disassembly.

Optionally, the second connector 433 is located on one side of the first connector 432 close to the pressurizing assembly 300. The second connector 433 may be of a block structure, such as a rectangular, square, circular, elliptical, or other regular polygonal plate. When the first connector 432 slides along the guide shaft 434 to the second connector 433, a force may be applied to the second connector 433, which in turn applies a force to the pressurizing assembly 300.

Optionally, the pressure sensor 435 is connected to the second connector 433. At this time, the heating and pressurizing device includes a pressurization state and a depressurization state; in the pressurization state, the first connector 432 is in contact with the pressure sensor 435 and exerts a force to subject the pressure sensor 435 to an acting force; in the depressurization state, there is a gap between the first connector 432 and the pressure sensor 435, or the first connector 432 is in contact with the pressure sensor 435 but does not generate an effective acting force (a value of the acting force detected by the pressure sensor 435 is 0).

The pressure sensor 435 is connected to a center position of the second connector 433 to enhance the accuracy of detection of the acting force. Preferably, the pressure sensor 435 has a pie-shaped structure, to better detect the acting force without affecting the contact between the first connector 432 and the second connector 433.

Further, in some embodiments of the present disclosure, as shown in FIG. 4, the slide head assembly 430 further includes a linear bearing 437 connected between the first connector 432 and the guide shaft 434. Specifically, the first connector 432 includes a mounting hole for mounting the linear bearing 437, and the linear bearing 437 is mounted in the mounting hole. One end of the guide shaft 434 slidably passes through the linear bearing 437.

When the power driving member 440 drives the first connector 432 and the slide block 431 to slide along the first slide rail 420, one end of the first connector 432 connected to the guide shaft 434 may slide along the guide shaft 434 under guidance of an extension direction of the guide shaft 434. When the first connector 432 slides along the guide shaft 434 to the second connector 433, an acting force may be applied to the second connector 433, and then an acting force may be applied to the pressurizing assembly 300.

Further, in some embodiments of the present disclosure, as shown in FIG. 4, the slide head assembly 430 further includes a limiting portion 436 connected to the guide shaft 434 and located on one side of the first connector 432 away from the second connector 433. The limiting portion 436 is used to delimit a sliding range of the first connector 432 along the guide shaft 434.

There may be various kinds of structures for the limiting portion 436. In a specific embodiment, the limiting portion 436 is of an integrated structure that is fixedly connected to an end of the guide shaft 434 away from the second connector 433. A section of the limiting portion 436 in the second direction X is larger than a size of the mounting hole on the first connector 432, which may block the mounting hole and allow the first connector 432 to slide within the delimited range. In another specific embodiment, the limiting portion 436 includes a plurality of parts, such as a first limiting portion 436 and a second limiting portion 436. The first limiting portion 436 is fixedly connected to one end of the guide shaft 434 away from the second connector 433; and the second limiting portion 436 is fixedly connected to a side surface of the first connector 432 away from the second connector 433 and located on one side of the first limiting portion 436 close to the second connector 433. The second limiting portion 436 is provided with a through-hole for the guide shaft 434 to pass through. A section of the first limiting portion 436 in the second direction X is larger than a size of the through-hole on the second limiting portion 436, which may block the through-hole on the second limiting portion 436 and allow the first connector 432 to slide within the delimited range.

In some embodiments, as shown in FIGS. 1, 3, and 4, the power driving member 440 includes a drive motor 441 and a power conversion element 442. The drive motor 441 is connected to a first support member 410 and is used to output rotational power. The power conversion element 442 has a power input end and a power output end 4421; the power input end of the power conversion element 442 is connected to the drive motor 441, and the power output end 4421 of the power conversion element 442 is connected to the slide head assembly 430; the power conversion element 442 is used to convert the rotational power output by the drive motor 441 into linear motion.

The drive motor 441 may be a servo motor configured to output the rotational power. The power conversion element 442 may convert the rotational power into the linear motion. Through this structural design, space utilization may be improved while meeting the movement requirements. The power conversion element 442 may be fixed to the first support member 410 through at least one fixing seat. The power conversion element 442 may be a ball screw. The two first rails of the first slide rail 420 may be located on front and rear sides of the power conversion element 442, i.e., front and rear sides of the ball screw.

In some embodiments of the present disclosure, as shown in FIG. 1, the power driving member 440 further includes a speed reducer 443 connected between the drive motor 441 and the power input end of the power conversion element 442. The speed reducer 443 is used to decrease an output speed of the drive motor 441 and increase a torque. The drive motor 441 itself has a high output speed and a low torque, and the speed reducer 443 has a function of decreasing a speed and increasing a torque. After the speed reducer 443 is mounted, the power conversion element 442 may provide a large torque and exert a large force that may reach 1 ton, which may satisfy many process requirements. The drive motor 441 and the speed reducer 443 may be connected by a key, and the power conversion element 442 and the speed reducer 443 may be connected by an elastic coupling.

In some embodiments of the present disclosure, as shown in FIG. 1 or FIG. 4, the driving mechanism 400 further includes the first support member 410, and the first slide rail 420 is connected to the first support member 410. The first support member 410 may be a support plate or a support column, and its cross-sectional shape may be circular, rectangular, square, or regular polygonal.

Preferably, the first support member 410 is a support plate extending along the first direction Z. The first slide rail 420 may be connected to the first support member 410 by bolts, screws, or other means. Specifically, there are two support plates located on both sides of the heating carrying mechanism 10 in the second direction X. The first slide rail 420 is connected to a surface of the first support member 410 that is in the second direction X and faces one side of the heating carrying mechanism 10.

In some embodiments of the present disclosure, as shown in FIG. 1 or FIG. 4, the driving mechanism 400 further includes at least one photoelectric sensor 450 on one side of the first slide rail 420. The photoelectric sensor 450 is used to sense a sliding position of the slide head assembly 430.

There are a plurality of photoelectric sensors 450. At least one photoelectric sensor 450 includes a first photoelectric sensor 450. The first photoelectric sensor 450 may have various functions. In one embodiment, the pressurizing assembly 300 brings the first substrate into contact with the second substrate, and the force generated by the contact is set with a force threshold, and the first photoelectric sensor 450 is arranged at a position corresponds to the force threshold. For example, when the force generated by the contact between the first substrate and the second substrate exceeds the force threshold, the first photoelectric sensor 450 may transmit this information to a structure such as an early warning system to generate an early warning signal, so as to avoid damaging the machine and causing safety hazards. Further, the first photoelectric sensor 450 may be used in conjunction with the pressure sensor 435 to enhance the safety factor.

In other embodiments, the position of the first photoelectric sensor 450 is used to delimit a sliding range of the slide head assembly 430 in the first direction Z, thereby providing a soft limitation for the slide head assembly 430 to prevent the slide head assembly 430 from exceeding the sliding range.

At least one photoelectric sensor 450 also includes a second photoelectric sensor 450 arranged on one side of the first photoelectric sensor 450 away from the heating platform. The position of the second photoelectric sensor 450 is used to correspond to an initial position of the slide head assembly 430; or the position of the second photoelectric sensor 450 is used to delimit the sliding range of the slide head assembly 430 in the first direction Z.

In a specific embodiment, the number of photoelectric sensors 450 is three, and the three photoelectric sensors 450 are arranged along the first direction Z, in which the photoelectric sensor 450 in the middle corresponds to a start position of the slide head assembly 430, and the remaining two photoelectric sensors 450 are used to delimit the sliding range of the slide head assembly 430 in the first direction Z, thereby providing the soft limitation for the slide head assembly 430 to prevent the slide head assembly 430 from exceeding the sliding range.

In some embodiments of the present disclosure, as shown in FIG. 1 or FIG. 4, the driving mechanism 400 further includes a second slide rail 470, which is connected to the first support member 410 and extends along the first direction Z. The second slide rail 470 is connected to a side surface of the first support member 410 in the third direction Y. For example, the first support member 410 is the support plate in the above embodiment, the support plate also has two side surfaces connecting inner and outer surfaces, and the second slide rail 470 is connected to one of the side surfaces.

In some embodiments of the present disclosure, as shown in FIG. 1 or FIG. 4, the driving mechanism 400 further includes a sensor limiting piece 460, one end of which is connected to the slide head assembly 430, and the other end of which extends along the second direction X towards the photoelectric sensor 450. Further, the photoelectric sensor 450 is provided with a limit slot 451 on one side close to the sensor limiting piece 460, and the other end of the sensor limiting piece 460 may be inserted into the limit slot 451. The sensor limiting piece 460 may assist in improving the accuracy of the photoelectric sensor 450 in sensing a sliding position of the driving assembly.

In some embodiments of the present disclosure, as shown in FIG. 1, the heating and pressurizing device further includes a base 30 that is mainly used to provide a support platform for the heating carrying mechanism 10 and the pressurizing driving mechanism 20. Specifically, the heating carrying mechanism 10 and the pressurizing driving mechanism 20 may be connected to one side of the base 30 in the first direction Z. The heating member 100 of the heating carrying mechanism 10 may be fixed to a side surface of the base 30. The second support member 500 may be connected between the base 30 and the carrying platform 200. A bottom end of the first support member 410 of the pressurizing driving mechanism 20 may be connected to the base 30.

Further, as shown in FIG. 1, the heating and pressurizing device further includes at least one base leveling member 40 connected between the base 30 and the second support member 500. The base leveling member 40 may be a leveling bolt. The size and shape of the base leveling member 40 may be set according to the shape and size of the cross-section of the second support member 500.

As shown in FIG. 1, the heating and pressurizing device also includes a reinforcement member 50 connected between the first support member 410 and the base 30. The reinforcement member 50 may be approximately a right-angled triangular plate or a right-angled trapezoidal plate to enhance the stability of the first support member 410 fixed to the base 30.

The pressurizing assembly included in the heating and pressurizing device will be explained in detail below.

As shown in FIGS. 2 and 5, the pressurizing assembly 300 includes a connecting portion 310 and a light-transmitting pressing plate 320. The connecting portion 310 has a hollow region 311 that runs through it. The connecting portion 310 is fixedly connected to the light-transmitting pressing plate 320 and is located on one side close to a first surface of the light-transmitting pressing plate 320. In the first direction Z, there is an overlapping region between a light-transmitting region AA of the light-transmitting pressing plate 320 and the hollow region 311.

In this way, when the laser of the target wavelength is irradiated onto the pressurizing assembly 300, the laser may sequentially pass through the hollow region 311 of the connecting portion 310 and the light-transmitting region 311 of the light-transmitting pressing plate 320, so as to realize laser irradiation on the first substrate connected to a second surface of the light-transmitting pressing plate 320, thereby achieving the effectiveness of peeling off or dissociating the light-emitting chips on the first substrate.

In addition, as shown in FIG. 5, the connecting portion 310 also has a pressurizing region 312 located at the periphery of the hollow region 311. The driving mechanism 400 is connected to the pressurizing region 312 of the connecting portion 310, so as to pressurizing the connecting portion 310 by the driving mechanism 400, achieve the contact between the first substrate and the second substrate, and generate the interaction force. There may be a plurality of pressurizing regions 312 symmetrically distributed around the hollow region 311. For example, the connecting portion 310 has two pressurizing regions 312 that are symmetrically distributed in the second direction X about the hollow region 311.

The connecting portion 310 has two surfaces that face away from each other in the first direction, and the hollow region 311 penetrates these two surfaces. The light-transmitting pressing plate 320 is located at a center position of the connecting portion 310 to ensure that the light-transmitting region 311 of the light-transmitting pressing plate 320 has a larger overlapping area with the hollow region 311 of the connecting portion 310. The connecting portion 310 may be made of steel to ensure that the connecting portion 310 has characteristics of high strength, high hardness, and being not easily deformed. The connecting portion 310 may be approximately a rectangular plate, and a long edge of the rectangular plate extends in the second direction X.

In the present disclosure, for fixation of the light-transmitting pressing plate 320 and the connecting portion 310, in some embodiments, as shown in FIG. 2, the pressurizing assembly 300 further includes a metal frame 330 between the connecting portion 310 and the light-transmitting pressing plate 320 (i.e., the metal frame 330 is located on one side close to the first surface of the light-transmitting pressing plate 320), and the light-transmitting pressing plate 320 and the metal frame 330 may be fixed to the connecting portion 310 by screws.

The metal frame 330 has a ring-shaped structure, and an orthographic projection of the metal frame on the light-transmitting pressing plate 320 surrounds the light-transmitting region AA of the light-transmitting pressing plate 320. That is, when the laser irradiation device generates laser for irradiation, the metal frame 330 will not block the laser from passing through the light-transmitting region AA of the light-transmitting pressing plate 320.

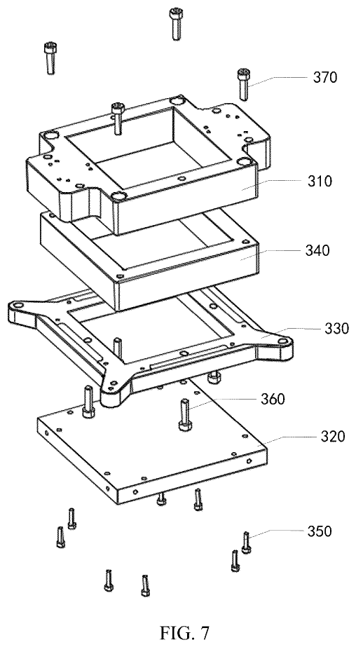

In other embodiments, as shown in FIGS. 6 and 7, the pressurizing assembly 300 further includes a metal frame 330 and an elastic pad 340. The metal frame 330 and the elastic pad 340 are both located on one side of the light-transmitting pressing plate 320 away from a second surface 321 (i.e., between the connecting portion 310 (not shown in the figure) and the light-transmitting pressing plate 320), and the metal frame 330 is located between the elastic pad 340 and the light-transmitting pressing plate 320. The metal frame 330 and the elastic pad 340 each have an annular structure, and orthographic projections of the metal frame 330 and the elastic pad 340 on the light-transmitting pressing plate 320 surround the light-transmitting region AA.

The elastic pad 340 may be a rubber pad with certain elasticity and compressible deformation. When the driving mechanism 400 drives the first substrate and the second substrate to generate the interaction force, problems, such as the surface parallelism of the light-transmitting pressing plate 320 and the potential inclination of the light-transmitting pressing plate 320 during assembly, may cause slight transverse displacement of the light-transmitting pressing plate 320 in a direction perpendicular to the first direction Z. Through the arrangement of the elastic pad 340, an elastic buffer may be formed between the light-transmitting pressing plate 320 and the connecting portion 310. When the driving mechanism 400 drives the first substrate and the second substrate to generate the interaction force, the elastic deformation of the elastic pad 340 may absorb the transverse displacement of the light-transmitting pressing plate 320 in the second direction X and/or the third direction Y, avoiding relative displacement between the light-transmitting pressing plate 320 and the first substrate, and thus avoiding friction between the light-transmitting pressing plate 320 and the first substrate and debris production, and meanwhile, avoiding a problem that the light-transmitting pressing plate 320 drives the first substrate to displace and misalign with the second substrate.

For fixation of the connecting portion 310, the light-transmitting pressing plate 320, the metal frame 330, and the elastic pad 340 included in the pressurizing assembly 300, in some embodiments, as shown in FIG. 7, the pressurizing assembly 300 also includes a first fixing bolt 350, a second fixing bolt 360, and a third fixing bolt 370. The light-transmitting pressing plate 320 has a first countersunk hole located on and penetrating a surface facing away from the metal frame 330; the metal frame 330 has a first threaded hole located on a surface facing the light-transmitting pressing plate 320; a centerline of the first countersunk hole coincides with a centerline of the first threaded hole; and the first fixing bolt 350 passes through the first countersunk hole and is tightened in the first threaded hole. The metal frame 330 has a second countersunk hole located on and penetrating the surface facing the light-transmitting pressing plate 320; the elastic pad 340 has a second threaded hole located on a surface facing the metal frame 330; a centerline of the second countersunk hole coincides with a centerline of the second threaded hole; and the second fixing bolt 360 passes through the second countersunk hole and is tightened in the second threaded hole. The connecting portion 310 has a third countersunk hole located on and penetrating a surface facing away from the elastic pad 340; the elastic pad 340 has a third threaded hole located on a surface facing the connecting portion 310; a centerline of the third countersunk hole coincides with a centerline of the third threaded hole; and the third fixing bolt 370 passes through the third countersunk hole and is tightened in the third threaded hole.

In an example where an outer contour of the light-transmitting pressing plate 320, an outer contour of the metal frame 330, an outer contour of the elastic pad 340, and an contour of the hollow region of the connecting portion 310 are all rectangular, optionally as shown in FIG. 7, each of four corners of the light-transmitting pressing plate 320 has two first countersunk holes, and correspondingly, the metal frame 330 has eight first threaded holes in one-to-one correspondence with eight first countersunk holes on the light-transmitting pressing plate 320, to achieve a fixed connection between the light-transmitting pressing plate 320 and the metal frame 330 through eight first fixing bolts 350. The metal frame 330 has a second countersunk hole in the middle of each side thereof, and correspondingly, the elastic pad 340 has four second threaded holes in one-to-one correspondence with four second countersunk holes, to achieve a fixed connection between the metal frame 330 and the elastic pad 340 through four second fixing bolts 360. Each corner of the connecting portion 310 has one third countersunk hole, and correspondingly, the elastic pad 340 has four third threaded holes in one-to-one correspondence with four third countersunk holes, to achieve a fixed connection between the metal frame 330 and the elastic pad 340 through four third fixing bolts 350. In such a case, the second fixing bolts 360 may be used to fixedly connect the metal frame 330 and the elastic pad 340, the third fixing bolts 370 may be used to fixedly connect the connecting portion 310 and the elastic pad 340, and then the first fixing bolts 350 may be used to fixedly connect the light-transmitting pressing plate 320 and the metal frame 330.

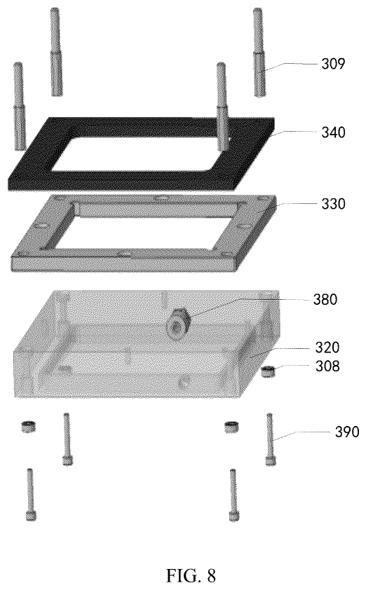

In some other embodiments, as shown in FIG. 8, the pressurizing assembly 300 further includes a fourth fixing bolt 390 and a locking nut 309. One end of the locking nut 309 is a threaded hole end, and the other end of the locking nut 309 is a threaded end. The light-transmitting pressing plate 320 has a fourth countersunk hole located on and penetrating the surface facing away from the metal frame 330. The metal frame 330 has a first through-hole, the elastic pad 340 has a second through-hole, and the connecting portion 310 (not shown in the figure) has a fourth threaded hole located on a surface facing the elastic pad 340. The centerline of the first countersunk hole, a centerline of the first through-hole, a centerline of the second through-hole, and a centerline of the fourth threaded hole coincide. The threaded end of the locking nut 309 is tightened into the fourth threaded hole of the connecting portion 310. The threaded hole end of the locking nut 309 sequentially passes through the second through-hole and the first through-hole, and extends into a small diameter end of the fourth countersunk hole. The fourth fixing bolt 390 extends into the fourth countersunk hole and is tightened at the threaded hole end of the locking nut 309.

In an example where the outer contour of the light-transmitting pressing plate 320, the outer contour of the metal frame 330, the outer contour of the elastic pad 340, and the contour of the hollow region of the connecting portion 310 are all rectangular, optionally as shown in FIG. 8, each of four corners of the light-transmitting pressing plate 320 has a fourth countersunk hole; correspondingly, the metal frame 330 has four first through-holes in one-to-one correspondence with four fourth countersunk holes on the light-transmitting pressing plate 320, the elastic pad 340 has four second through-holes in one-to-one correspondence with the four fourth countersunk holes, and the connecting portion 310 has four fourth threaded holes in one-to-one correspondence with the four fourth countersunk holes, to achieve the fixed connection of the connecting portion 310, the light-transmitting pressing plate 320, the metal frame 330, and the elastic pad 340 through four fourth fixing bolts 390 and four locking nuts 309. In such a case, the locking nuts 309 may be fixed on the connecting portion 310; then the elastic pad 340, the metal frame 330, and the light-transmitting pressing plate 320 may be sequentially fitted over the locking nuts 309; and afterwards the fourth fixing bolts 390 may be pressed on the light-transmitting pressing plate 320 and fixedly connected to the locking nuts 309.

In addition, as shown in FIG. 8, the pressurizing assembly 30 also includes a washer 308 fitted over the fourth fixing bolt 390 and limited in the fourth countersunk hole of the light-transmitting pressing plate 320 by a screw head of the fourth fixing bolt 390, to provide an elastic margin through the washer 308, thereby achieving elastic buffering when the pressurizing assembly 30 is fixed.

Compared to the second fixing method mentioned above, the first fixing method may separately achieve the fixed connection of any adjacent two structural members, thereby reducing the machining accuracy of the countersunk holes or threaded holes on various structural members. Meanwhile, compared to a situation where the locking nut 309 passes through the first through-hole and the second through-hole in the second fixing method, the first fixing method may avoid shaking of the metal frame 330 and the elastic pad 340 caused by machining errors, thereby ensuring the stability of the fixed connection of the connecting portion 310, the light-transmitting pressing plate 320, the metal frame 330, and the elastic pad 340.

In the present disclosure, for the light-transmitting pressing plate 320 included in the pressurizing assembly 300, in combination with the transfer process of the light-emitting chips described above, in order to achieve the integrated operation of the light-emitting chips in mass transfer, the light-transmitting pressing plate 320 needs to have a pressure-bearing property during pressurization and a light-transmission property during laser dissociation, and also needs to ensure that the first substrate and the second substrate are separated properly.

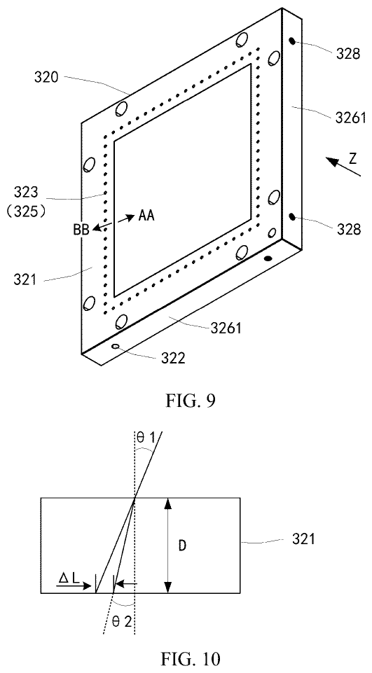

In some embodiments, as shown in FIG. 9, the light-transmitting pressing plate 320 includes a first surface (not shown in the figure) and a second surface 321 that are parallel to each other and extend along a plane. The light-transmitting pressing plate 320 allows a laser of a target wavelength to be transmitted in a first direction Z pointing from the first surface to the second surface 321. The light-transmitting pressing plate 320 is used to transfer the light-emitting chips attached to the first substrate to the second substrate under pressure and under the action of the laser of the target wavelength. The first substrate is located on one side of the light-transmitting pressing plate 320 close to the second surface 321, and allows the laser of the target wavelength to be transmitted in the first direction Z. The first substrate and the second substrate are located on a same side of the light-transmitting pressing plate 320, and the first substrate is closer to the light-transmitting pressing plate 320 than the second substrate.

As a result, the feasibility of pressure bearing is achieved through the light-transmitting pressing plate 320, and since the light-transmitting pressing plate 320 may transmit the laser of the target wavelength in the first direction Z, the feasibility of laser irradiation is realized, which achieves the feasibility of integrating pressurization and laser irradiation, simplifies the process of mass transfer of the light-emitting chips, and improves the production efficiency.

For example, the transmittance of the light-transmitting pressing plate 320 for the laser of the target wavelength is greater than or equal to 80%. Further, the transmittance of the light-transmitting pressing plate 320 for the laser of the target wavelength is greater than or equal to 90%. Further, the transmittance of the light-transmitting pressing plate 320 for the laser of the target wavelength is greater than or equal to 92%. Consequently, a transmission effect of the light-transmitting pressing plate 320 for the laser of the target wavelength may be ensured, which may guarantee a laser transmission effect of the light-transmitting region AA generated by the laser irradiation device during laser dissociation, and guarantee a dissociation effect of the light-emitting chips on the first substrate when the laser irradiates the first substrate.

When the laser passes through the light-transmitting pressing plate 320 and irradiates the first substrate, in order to ensure that the transmittance of the light-transmitting pressing plate 320 for the laser of the target wavelength is greater than 92%, a lens body (double flat mirror structure) with a transmittance of greater than 92% may be directly selected as the light-transmitting pressing plate 320, or a lens body with an anti-reflection film affixed to the surface may be selected as the light-transmitting pressing plate 320. Usually, the transmittance of the lens body affixed with the anti-reflection film may reach up to 99%.

For example, the target wavelength may be within 390 nm-780 nm, such as visible light; or within a range of 780 nm-2000 nm, such as infrared light; or within a range of 100 nm-390 nm, such as ultraviolet light. Specifically, the target wavelength may be within one of the following ranges: 770 nm˜622 nm (red light), 622 nm˜597 nm (orange light), 597 nm˜577 nm (yellow light), 577˜492 nm (green light), 492 nm˜450 nm (cyan light), 450 nm˜435 nm (blue light), 455 nm˜350 nm (purple light). More specifically, the target wavelength is 355 nm.

The lens body may be approximately a rectangular prism, a cube, a polygonal prism, or a cylinder. A material of the lens body (i.e., a material of the light-transmitting pressing plate) may be a glass product (e.g., fused quartz glass, synthetic quartz glass, and natural quartz glass), a crystalline or amorphous inorganic nonmetal, etc., and only needs to satisfy the transmittance, the pressure-bearing property (withstanding a pressure intensity of greater than or equal to 0.5 MPa) and the high temperature resistance (withstanding a temperature of greater than or equal to 150° C.). Exemplarily, the material of the lens body is silicon dioxide. Exemplarily, the material of the lens body is magnesia sand quartz glass. Exemplarily, the material of the lens body may be JGS1 quartz glass, to ensure high transmittance of the light-transmitting pressing plate 320 for the laser of the target wavelength (e.g., 355 nm), while achieving low cost of the light-transmitting pressing plate 320. JGS1 quartz glass refers to glass made by melting a synthetic stone and a high-purity oxyhydrogen flame and due to a large amount of hydroxyl groups (about 2000 ppm), may have excellent light transmittance especially in the short-wave ultraviolet band, the transmittance being far superior to all other types of glass, and a UV transmittance for 185 nm UV reaching over 90%. Exemplarily, the material of the lens body may be JGS2 quartz glass or JGS3 quartz glass. Exemplarily, the material of the lens body may be one of Corning 7978 quartz glass, Corning 7979 quartz glass, or Corning 7980 quartz glass.

For a situation where the light-transmitting pressing plate 320 only includes a lens body, when the laser passes through the lens body, due to a high damage threshold of the lens body, damage to the lens body caused by accumulation of heat on the surface of the lens body may be avoided. For a situation where the light-transmitting pressing plate 320 includes a lens body and an anti-reflection film, the first surface and/or the second surface 321 of the lens body have the anti-reflection film; in addition, when the laser passes through the anti-reflection film, heat will accumulate on the anti-reflection film, in which case the damage threshold for the surface of the lens body may be set to be greater than or equal to 7.5 J/cm² to avoid damage to the anti-reflection film caused by the accumulated heat. Exemplarily, the damage threshold of the anti-reflection film is 7.5 J/cm², 8 J/cm², 8.5 J/cm², 9 J/cm², etc.

It should be noted that for a situation where the light-transmitting pressing plate 320 is the lens body, taking the light-transmitting pressing plate 320 with a thickness of 10 mm as an example, the light transmittance is tested, and the test data is shown in the table below.

| laser energy | 2960 | 2450 | 2040 | 1730 | 1490 | 1300 | 1140 | 1000 | 887 |
|---|---|---|---|---|---|---|---|---|---|
| without planar | | | | | | | | | |
| lens | | | | | | | | | |
| laser energy with | 2740 | 2270 | 1890 | 1600 | 1380 | 1200 | 1050 | 931 | 826 |
| planar lens | | | | | | | | | |
| percentage of | 7.43% | 7.35% | 7.35% | 7.51% | 7.38% | 7.69% | 7.89% | 6.90% | 6.88% |
| energy attenuation | | | | | | | | | |
| laser energy | 794 | 713 | 644 | 588 | 534 | 490 | 451 | 418 | 388 |
| without planar | | | | | | | | | |
| lens | | | | | | | | | |
| laser energy with | 740 | 667 | 603 | 549 | 499 | 459 | 423 | 391 | 362 |
| planar lens | | | | | | | | | |
| percentage of | 6.80% | 6.45% | 6.37% | 6.63% | 6.55% | 6.33% | 6.21% | 6.45% | 6.70% |
| energy attenuation | | | | | | | | | |
| laser energy | 357 | 335 | 316 | 296 | 280 | 264 | 251 | 238 | 227 |
| without planar | | | | | | | | | |
| lens | | | | | | | | | |
| laser energy with | 336 | 313 | 294 | 275 | 259 | 244 | 230 | 218 | 208 |
| planar lens | | | | | | | | | |
| percentage of | 5.88% | 6.57% | 6.96% | 7.09% | 7.50% | 7.58% | 8.37% | 8.40% | 8.37% |
| energy attenuation | | | | | | | | | |
| laser energy | 218 | 207 | 200 | 190 | 183 | 178 | 172 | 167 | 162 |
| without planar | | | | | | | | | |
| lens | | | | | | | | | |
| laser energy with | 199 | 189 | 182 | 174 | 169 | 161 | 147 | 151 | 153 |
| planar lens | | | | | | | | | |
| percentage of | 8.72% | 8.70% | 9.00% | 8.42% | 7.65% | 9.55% | 14.53% | 9.58% | 5.56% |
| energy attenuation | | | | | | | | | |

According to the test data shown in the table above, the average light loss of the light-transmitting pressing plate 320 with a thickness of 10 mm is 7.37% to ensure that the transmittance of the light-transmitting pressing plate 320 is greater than 92%.

In the present disclosure, when the laser generated by the laser irradiation device irradiates the light-transmitting pressing plate 320, the laser that perpendicularly passes through the light-transmitting region AA will not undergo refraction, in which case an optical path of the laser remains unchanged, avoiding offset of a light spot position of the laser irradiation on the first substrate; the laser that obliquely (i.e., not parallel to the first direction Z) passes through the light-transmitting region AA will undergo refraction, resulting in an increase in the optical path of the laser, which in turn results in an offset of the light spot of the laser irradiation on the first substrate. When the offset of the light spot formed by the laser on the first substrate is large, especially for the laser irradiation of one dotting site corresponding to one light-emitting chip mentioned above, it is easy to cause some light-emitting chips to be unable to be effectively peeled off or dissociated from the first substrate.

When the laser irradiates the light-transmitting pressing plate 320 from a vacuum environment, according to Snell's law, a relationship between an incident angle, a refractive angle, and a refractive index of two media may be expressed as: n1*sin θ1=n2*sin θ2, wherein n1 and θ1 respectively refer to the refractive index and the incident angle of the laser in the vacuum environment, and n2 and θ2 respectively refer to the refractive index and the refractive angle of the laser within the light-transmitting pressing plate 320. Since n1 takes a constant of 1, the refractive index n2 of the laser in the light-transmitting pressing plate 320 and the incident angle of the laser may be combined to determine the refractive angle of the laser, which in turn may be combined with FIG. 10 to calculate the offset of the light spot formed by the laser irradiation on the first substrate according to the following formula:

$$Δ L = ( tan θ1 - tan θ2 ) / D$$

In the above formula, ΔL refers to the offset of the light spot on the first substrate, 01 refers to the incident angle of the laser, 02 refers to the refractive angle of the laser, and D refers to a thickness of the light-transmitting pressing plate 320 (i.e., a thickness of the light-transmitting region AA of the light-transmitting pressing plate 320).

Based on the above, it may be known that the factors affecting the offset of the light spot on the first substrate include at least the refractive index of the laser in the light-transmitting pressing plate 320 and the thickness of the light-transmitting pressing plate 320. The higher the refractive index of the laser in the light-transmitting pressing plate 320 is, the smaller the refractive angle is, which in turn leads to a larger offset of the light spot. Moreover, the thicker the light-transmitting pressing plate 320 is, the larger the offset of the light spot is.

For the refractive index of the laser within the light-transmitting pressing plate 320, for a certain medium, the refractive index of the laser is n=c/v, and the propagation frequency of the laser is a fixed value. At this time, the propagation speed of the laser is v=f*λ, which may be brought into the above equation of refractive index to obtain the refractive index of the laser as n=c/(f*λ). Therefore, when the laser enters the light-transmitting pressing plate 320 from the vacuum medium, for the obliquely transmitted laser, the relationship between the refractive index and the wavelength of the laser in two different media may be obtained as n1/n2=λ2/λ1.

Among them, n, v, and λ respectively refer to the refractive index, the propagation speed, and the wavelength of the laser in a same medium; c refers to the propagation speed of the laser in vacuum; f refers to the propagation frequency of the laser; n1 and λ1 respectively refer to the refractive index and the wavelength of the laser in vacuum medium; n2 and λ2 respectively refer to the refractive index and the wavelength of the laser in the light-transmitting pressing plate 320.

Accordingly, there is a certain relationship between the wavelength of the laser and the refractive index of the propagation medium (the light-transmitting pressing plate 320), that is, the shorter the wavelength of the laser is, the higher the refractive index of the laser in the light-transmitting pressing plate 320 is. Exemplarily, in combination with the situation where the higher the refractive index is, the greater the offset of the light spot is, and considering a minimum thickness of the light-transmitting pressing plate 320 involved in the present disclosure, it is necessary to select a double flat mirror structure with a refractive index of less than 1.6 for the laser with a wavelength of 355 nm, that is, the refractive index of the light-transmitting pressing plate 320 involved in the present disclosure for the laser with the wavelength of 355 nm is less than 1.6 (i.e., the refractive index of the light-transmitting pressing plate 320 is greater than 1 and less than 1.6), in order to avoid a smaller wavelength of the laser and a larger offset of the light spot on the first substrate. When the refractive index of the light-transmitting pressing plate 320 is greater than or equal to 1.6, the offset of the light spot of the laser irradiation on the first substrate is large, which easily affects the peel-off or dissociation effect of the light-emitting chips on the first substrate.

Preferably, the refractive index of the light-transmitting pressing plate 320 for the laser with the wavelength of 355 nm is greater than 1 and less than 1.46, to further ensure the peel-off or dissociation effect of the light-emitting chips on the first substrate. Exemplarily, the refractive index of the light-transmitting pressing plate 320 for the laser with the wavelength of 355 nm may be 1.1, 1.2, 1.3, 1.4, etc.

For the thickness of the light-transmitting pressing plate 320, as the thickness of the light-transmitting pressing plate 320 increases, the size of the light spot on the first substrate will also change. Exemplarily, for an incident angle of 0.705 and a refractive index of 1.45, combined with different thicknesses of the light-transmitting pressing plate 320, a size change and an expected size of the light spot on the first substrate are shown in the following table.

| incident | refractive | | thickness of | size change of | expected size |
|---|---|---|---|---|---|
| angle | index | exit angle | planar lens | light spot | of light spot |
| 0.705 | 1.45 | 0.46331 | 0.5 | 0.17564 | 132.3513 |
| 0.705 | 1.45 | 0.46331 | 1 | 0.35128 | 132.7026 |
| 0.705 | 1.45 | 0.46331 | 2 | 0.70256 | 133.4051 |
| 0.705 | 1.45 | 0.46331 | 3 | 1.05385 | 134.1077 |
| 0.705 | 1.45 | 0.46331 | 4 | 1.40513 | 134.8103 |
| 0.705 | 1.45 | 0.46331 | 5 | 1.75641 | 135.5128 |
| 0.705 | 1.45 | 0.46331 | 6 | 2.10769 | 136.2154 |
| 0.705 | 1.45 | 0.46331 | 7 | 2.45898 | 136.9179 |
| 0.705 | 1.45 | 0.46331 | 8 | 2.81026 | 137.6205 |
| 0.705 | 1.45 | 0.46331 | 9 | 3.16154 | 138.3201 |
| 0.705 | 1.45 | 0.46331 | 10 | 3.51282 | 139.0256 |
| 0.705 | 1.45 | 0.46331 | 16 | 5.62052 | 143.2410 |
| 0.705 | 1.45 | 0.46331 | 20 | 7.02564 | 146.0513 |

As shown in the above table, the light spot on the first substrate enlarges as the thickness of the light-transmitting pressing plate 320 increases, and after binary fitting of the thickness of the light-transmitting pressing plate 320 and the expected size of the light spot, an approximately linear correspondence may be obtained. In addition, considering the situation where the thicker the light-transmitting pressing plate 320 is, the greater the offset of the light spot is, the thickness of the light-transmitting pressing plate 320 may be set to be less than or equal to 35 mm, that is, a distance between the first surface and the second surface 321 of the light-transmitting pressing plate 320 is less than or equal to 35 mm. Preferably, the thickness of the light-transmitting pressing plate 320 may be set to be less than or equal to 20 mm to minimize the offset of the light spot on the first substrate.

In addition, as the thickness of the light-transmitting pressing plate 320 decreases, the structural strength of the light-transmitting pressing plate 320 will also decrease, and the pressure bearing capacity will be weaker. Therefore, in order to ensure that the light-transmitting pressing plate 320 has a certain structural strength and in turn has a certain pressure-bearing property, the thickness of the light-transmitting pressing plate 320 may be set to be greater than or equal to 8 mm (i.e., the distance between the first surface and the second surface 321 of the light-transmitting pressing plate 320 is greater than or equal to 8 mm), to avoid a situation where the light-transmitting pressing plate 320 is damaged due to extrusion when the first substrate and the second substrate come into contact and generate interaction force.

Based on the above, the thickness of the light-transmitting pressing plate 320 is greater than or equal to 8 mm and less than or equal to 35 mm (i.e., the distance between the first surface and the second surface 321 of the light-transmitting pressing plate 320 is greater than or equal to 8 mm and less than or equal to 35 mm), which ensures the pressure bearing capacity of the light-transmitting pressing plate 320 and avoids the situation where the light-transmitting chips cannot be effectively dissociated due to the offset of the light spot on the first substrate caused by the excessive thickness of the light-transmitting pressing plate 320. Exemplarily, the thickness of the light-transmitting pressing plate 320 may be set to 8 mm, 12 mm, 16 mm, 20 mm, etc.

In the present disclosure, it is found that the peel-off or dissociation effect of some light-emitting chips on the first substrate is not ideal when the laser irradiates on the first substrate. After careful and meticulous research, the inventors have found that the energy distribution in a region of each of some light spots formed by the laser on the first substrate is not uniform, which may lead to ineffective dissociation of the dissociating adhesive in some regions of the first substrate, resulting in an unsatisfactory peel-off or dissociation effect of some light-emitting chips.

For the light-transmitting pressing plate 320 with different thicknesses, the inventors have found through experimental data that the thickness of the light-transmitting pressing plate 320 only affects the transmission of laser from a geometric optical perspective and does not affect the uniformity of a single light spot on the first substrate. After careful and meticulous research, the inventors have found that the surface parallelism of the light-transmitting region AA on the light-transmitting pressing plate 320 and the contents of the light-transmitting region AA may affect the uniformity of the light spot on the first substrate.

For the surface parallelism of the light-transmitting region AA, when the laser passes through the light-transmitting region AA of the light-transmitting pressing plate 320, the first surface and the second surface 321 of the light-transmitting pressing plate 320 are not strictly flat surfaces in the light-transmitting region AA, but may cause reflection, refraction or the like of the laser, which in turn leads to uniform light spots formed on the first substrate, resulting in poor peel-off or dissociation of the light-emitting chips on the first substrate.

The first surface and the second surface 321 of the light-transmitting pressing plate 320 are both flat surfaces, and the parallelism of the first surface and the second surface 321 in the light-transmitting region AA is less than or equal to 0.006 mm. Exemplarily, the parallelism of the first surface and the second surface 321 in the light-transmitting region AA is 0.004 mm, 0.005 mm, and 0.006 mm. Certainly, the parallelism of the first surface and the second surface 321 in the light-transmitting region AA may also be slightly greater than 0.006 mm, as long as the uniformity of the light spot formed on the first substrate may be ensured and the uneven distribution of laser energy in the region where the light spot is formed may be avoided.

Preferably, the parallelism of the first surface and the second surface 321 in the light-transmitting region AA is less than or equal to 0.003 mm. Exemplarily, the parallelism of the first surface and the second surface 321 in the light-transmitting region AA is 0.002 mm, 0.0025 mm, and 0.003 mm.

In addition, for a situation where the first surface and the second surface 321 of the light-transmitting pressing plate 320 are flat surfaces, it can not only ensure the uniformity of the light spot on the first substrate, but also ensure the uniformity of the force exerted by the light-transmitting pressing plate 320 on the first substrate, thereby ensuring that all the light-emitting chips on the first substrate may effectively adhere to the second substrate.

For the contents in the light-transmitting region AA, the contents in the light-transmitting pressing plate 320 (such as small bubbles, impurities, etc.) may also cause reflection, refraction or the like of the laser, resulting in unevenness of the light spot on the first substrate. In this way, the particle size of the contents of the light-transmitting pressing plate 320 may be set to be less than 0.1 mm to reduce the influence of the contents of the light-transmitting pressing plate 320 on the reflection, refraction or the like of the laser, thereby ensuring the uniformity of the light spot formed on the first substrate.

Exemplarily, the particle size of the contents of the light-transmitting pressing plate 320 is 0.04 mm, 0.06 mm, 0.08 mm, 0.1 mm, etc. Certainly, the particle size of the contents inside the light-transmitting pressing plate 320 may also be slightly larger than 0.1 mm, such as 0.11 mm, as long as it does not affect the uniformity of the light spot formed on the first substrate.

It should be noted that the transmittance, refractive index, thickness, surface parallelism, and contents of the light-transmitting pressing plate 320 described above in the present disclosure are all explained based on the light-transmitting region of the light-transmitting pressing plate 320 for transmission of the laser with the target wavelength.

Additionally, in the present disclosure, the refractive index, thickness, surface parallelism, and contents of the light-transmitting pressing plate 320 described above are combined to ensure the optical effect of the light-transmitting pressing plate 320.

Optionally, the light-transmitting pressing plate 320 has a light spot offset of less than or equal to 0.5 mm when transmitting the laser at an incident angle range of less than or equal to 14 degrees. Further, the light-transmitting pressing plate 320 has a light spot offset of less than or equal to 200 μm when transmitting the laser at an incident angle range of less than or equal to 14 degrees. In this way, the laser of the target wavelength passes through the light-transmitting region of the light-transmitting pressing plate and forms the light spot on the first substrate, avoiding the situation where the light spot cannot effectively dissociate the dissociating adhesive between the first substrate and the light-emitting chips due to a large offset, and ensuring the dissociation effect of massive light-emitting chips on the first substrate.

It should be noted that the above-mentioned light spot offset may be a test effect when a laser with a wavelength of 355 nm is transmitted through the light-transmitting region AA on the light-transmitting pressing plate 320, and forms a 132 μm*132 μm light spot; certainly, it may also be a test effect when a laser with other wavelengths is transmitted through the light-transmitting region AA on the pressure plate 320 and forms a light spot of other sizes.

Optionally, after the light-transmitting pressing plate 320 transmits laser within an A mm×B mm laser field, the degradation of the uniformity of the laser light spot does not exceed 2%, in which both A and B are less than or equal to 70. In this way, by setting the region size of the laser field on the light-transmitting pressing plate 320, the uniformity of the laser light spot in the region corresponding to the entire laser field, that is, the uniformity of the laser energy in the region corresponding to the entire laser field, can be ensured so as to avoid the situation where the light-emitting chips in a local region on the first substrate cannot be effectively dissociated, thus improving the transfer yield of the light-emitting chips. Exemplarily, the size of the laser field on the light-transmitting pressing plate 320 is 70 mm×70 mm, 60 mm×70 mm, 50 mm×70 mm, 60 mm×60 mm, etc.

Exemplarily, in a region with a laser field of 70 mm×70 mm, when the size of the light spot of the incident laser is a square with a side length of 6 mm and the size of the light spot of the exit laser is a square with a side length of 137.5 μm, the uniformity of the laser light spot without addition of the light-transmitting pressing plate 320 is 82%, and the uniformity of the laser light spot after addition of the thick light-transmitting pressing plate 320 with a thickness of 10 mm is 83.5. Therefore, by adding the light-transmitting pressing plate 320, the uniformity of the laser light spot is effectively improved, and the dissociation effect of the light-emitting chips on the first substrate is ensured. For a situation with the addition of the light-transmitting pressing plate 320, when the laser passes through the light-transmitting region AA of the light-transmitting pressing plate 320, the contents inside the light-transmitting region AA on the light-transmitting pressing plate 320 may adjust the refractive angle of the laser to improve the uniformity of the laser light spot. For example, the contents of the light-transmitting pressing plate 320 may be one or more of bubbles, scattering particles (e.g., silica particles, etc.) or the like. In this way, during preparation of the light-transmitting pressing plate 320, uniformly distributed contents may be added to the light-transmitting region AA of the light-transmitting pressing plate 320 to effectively improve the uniformity of the laser light spot.

Optionally, after the light-transmitting pressing plate 320 transmits laser within an incident angle range of less than or equal to 14 degrees, the uniformity of the laser light spot is equivalent to or superior to the uniformity of the laser light spot before incidence. In this way, by ensuring the uniformity of the laser light spot, that is, ensuring the uniformity of the laser energy in the region where the laser light spot is located, the light-emitting chips in the region where the laser light spot is located may be effectively dissociated, thereby improving the transfer yield of the light-emitting chips. Based on the above example, it may be seen that the uniformity of the laser light spot is optimized after the laser with the wavelength of 355 nm is transmitted through the light-transmitting region AA of the light-transmitting pressing plate 320 with the thickness of 10 mm.

In the present disclosure, when the driving mechanism 400 drives the light-transmitting pressing plate 320 to bring the first substrate into contact with the second substrate and generate interaction force, the first substrate may be directly placed in alignment with the second substrate, and then the driving mechanism 400 may apply pressure on the first substrate during the movement of the light-transmitting pressing plate 320, to achieve the interaction force between the first substrate and the second substrate. Alternatively, the first substrate may be first fixed on the second surface 321 of the light-transmitting pressing plate 320, and then the driving mechanism 400 may apply pressure on the first substrate during the movement of the light-transmitting pressing plate 320, to achieve the contact and generate the interaction force between the first substrate and the second substrate.

For a situation where the first substrate is fixed to the second surface 321 of the light-transmitting pressing plate 320, the first substrate may adhere to the second surface 321 of the light-transmitting pressing plate 320 by a dissociating adhesive that is easy to peel off, or fixed to the second surface of the light-transmitting pressing plate 320 by adsorption. Next, the structure of the light-transmitting pressing plate 320 will be explained in terms of the first substrate being fixed by adsorption.

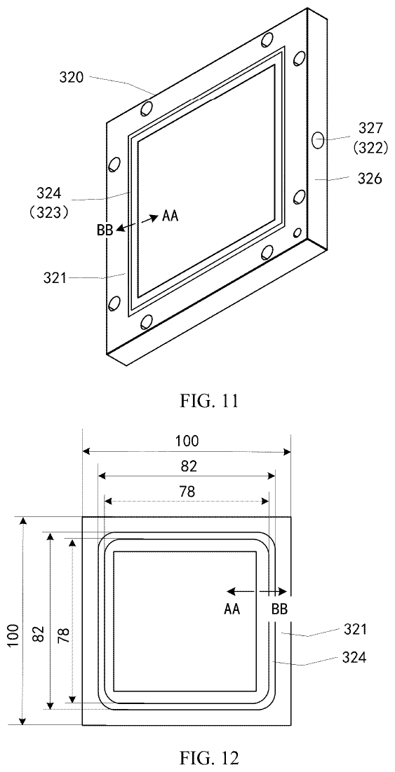

As shown in FIG. 9 or FIG. 11, the light-transmitting pressing plate 320 includes a light-transmitting region AA and a peripheral region BB, with the peripheral region BB surrounding the light-transmitting region AA. There is a first gas passage (not shown in the figure) in the peripheral region BB, the first gas passage has a first adsorption port 323 extending to the second surface 321, and the first adsorption port 323 is distributed around the light-transmitting region AA. In addition, the first gas passage also has a first gas extraction port 322 extending to the first surface and/or the side wall of the light-transmitting pressing plate 320. The first gas extraction port 322 is used to connect a gas extraction device, to facilitate adsorption and fixation of the first substrate through the first adsorption port 323.

In this way, by providing the first gas passage in the peripheral region BB of the light-transmitting pressing plate 320 to form the first adsorption port 323 on the second surface 321, stable adsorption of the first substrate is ensured, and meanwhile the influence on the laser is avoided to ensure the light spot effect of the laser passing through the light-transmitting region AA.

Exemplarily, in combination with the thickness of the light-transmitting pressing plate 320 described above, in an example where the thickness of the light-transmitting pressing plate 320 is 8 mm and the first gas extraction port 322 is located on the side wall of the light-transmitting pressing plate 320, the first gas extraction port 322 is provided with a 7 mm straight-through joint 380 to facilitate direction connection with the gas extraction device and ensure the structural strength of the light-transmitting pressing plate 320.

In the embodiments of the present disclosure, when the first substrate is adsorbed by the light-transmitting pressing plate 320, in order to ensure effective separation between the first substrate and the second substrate, it is necessary to ensure that an adsorption force of the light-transmitting pressing plate 320 on the first substrate is greater than a molecular force between the first substrate and the second substrate.

When the first substrate is adsorbed by the light-transmitting pressing plate 320, fixation of the first substrate may be achieved by negative pressure adsorption. Exemplarily, the fixation of the first substrate may be achieved through vacuum adsorption.

Typically, the first substrate is adsorbed onto the light-transmitting pressing plate 320 along the first direction Z (i.e., the vertical direction), and the magnitude of the adsorption force of the light-transmitting pressing plate 320 on the first substrate may be calculated by following formula:

$$F = 0.1 \times A \times P / S ;$$

In the above formula, F refers to the adsorption force of the light-transmitting pressing plate 320 on the first substrate, measured in Newton; A refers to an effective adsorption area of the first adsorption port 323 on the second surface 321, measured in cm²; P refers to a vacuum degree of the gas passage when the light-transmitting pressing plate 320 adsorbs the first substrate, measured in kPa; S refers to a safety factor, and S is greater than or equal to 2.

Based on the above formula, it may be known that the adsorption force of the light-transmitting pressing plate 320 on the first substrate varies positively with the vacuum degree and the safety factor, that is, as the vacuum degree or the safety factor increases, the adsorption force will increase. In conventional use, the vacuum degree at which the light-transmitting pressing plate 320 adsorbs the first substrate is greater than or equal to 80 kPa, and thus a minimum adsorption force of the light-transmitting pressing plate 320 on the first substrate is 4A (unit: Newton). Combined with the experimental data, the molecular force between the first substrate and the second substrate is usually greater than or equal to 1 Newton and less than or equal to 5 Newtons. Therefore, in order to ensure that the adsorption force of the light-transmitting pressing plate 320 on the first substrate is greater than the molecular force between the first substrate and the second substrate, that is, 4A is greater than 5 Newtons, it may be concluded that A is greater than 1.25 cm², which means that the effective adsorption area of the first adsorption port 323 on the second surface 321 is greater than 1.25 cm².

It should be noted that when the light-transmitting pressing plate 320 adsorbs the first substrate, if the vacuum degree is less than 80 kPa, the effective adsorption area of the first adsorption port 323 on the second surface 321 of the light-transmitting pressing plate 320 may also be less than or equal to 1.25 cm², as long as it may ensure the normal separation between the first substrate and the second substrate after the light-transmitting pressing plate 320 adsorbs the first substrate. In addition, if the molecular force between the first substrate and the second substrate is less than 5 Newtons, the effective adsorption area of the first adsorption port 323 on the second surface 321 of the light-transmitting pressing plate 320 may also be less than or equal to 1.25 cm². This embodiment is not limited by the present disclosure.

In some embodiments, as shown in FIG. 11, the light-transmitting pressing plate 320 includes a contour surface 326 between the first surface and the second surface 321. The first gas passage includes a ring-shaped groove 324 and a vent hole 327. An opening of the ring-shaped groove 324 is located in the second surface 321 and forms the first adsorption port 323. One end of the vent hole 327 is in communication with the ring-shaped groove 324, and an opening of the other end of the vent hole 327 is located in the contour surface 326 and forms the first gas extraction port 322. The first gas extraction port 322 is used to be in communication with the gas extraction device.

The ring-shaped groove 324 is a square ring-shaped groove, a rectangular ring-shaped groove, a circular ring-shaped groove, etc., which will not be limited in the present disclosure. Specifically, the shape of the ring-shaped groove 324 may be determined based on the shape of the outer contour of the light-transmitting region AA, as long as it may stably adsorb and fix the first substrate without affecting the transmission of laser in the light-transmitting region AA. For the shape of the outer contour of the light-transmitting region AA, it may be designed in combination with the shape of the outer contour of the light-emitting chip on the first substrate to ensure that the laser transmission through the light-transmitting region AA may effectively dissociate the dissociating adhesive that bonds the light-emitting chip.

Exemplarily, the shape of the outer contour of each light-emitting chip on the first substrate is square. In such a case, the shape of the outer contour of the light-transmitting region AA on the light-transmitting pressing plate 320 may be designed as a square, and the ring-shaped groove 324 may be configured as a square ring-shaped groove to ensure the stable adsorption and fixation of the first substrate while reducing the size of the light-transmitting pressing plate 320.

Optionally, the ring-shaped groove 324 may be a square ring-shaped groove, and an inner ring of the square ring-shaped groove has a side length greater than or equal to 75 mm and less than or equal to 80 mm. Exemplarily, the side length of the ring-shaped groove 324 are 75 mm, 77 mm, 79 mm, and 80 mm. In this way, it is ensured that a sufficiently large laser field may be designed as the light-transmitting region AA on the light-transmitting pressing plate 320, thereby ensuring that the light spot formed by the laser through the light-transmitting region AA on the first substrate may completely cover the dissociating adhesive for fixing the light-emitting chips.

In combination with the effective adsorption area of the first adsorption port 323 on the second surface 321 of the light-transmitting pressing plate 320 described above being greater than 1.25 cm², a groove width of the square ring-shaped groove may be set to be greater than or equal to 0.42 mm. Exemplarily, the groove width of the square ring-shaped groove is 0.5 mm, 1.0 mm, 1.5 mm, and 2.0 mm.

Further, the groove width of the ring-shaped groove 324 may be set to be less than or equal to 1 mm. Exemplarily, the groove width of the ring-shaped groove 324 is 0.42 mm, 0.62 mm, 0.82 mm, and 1.0 mm. Thus, a situation where the size of the light-transmitting pressing plate 320 is too large may be avoided while ensuring the stability of absorbing the first substrate by the first adsorption port 323 of the square ring-shaped groove.

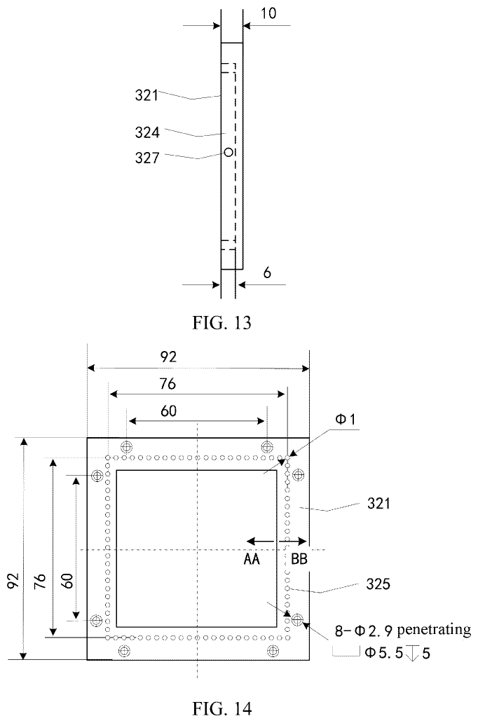

In a specific embodiment, as shown in FIGS. 12 and 13, the light-transmitting pressing plate 320 is a cube with a side length of 100 mm and a thickness of 10 mm. The ring-shaped groove 324 on the second surface 321 of the light-transmitting pressing plate 320 is a square ring-shaped groove, and a side length of an inner ring of the square ring-shaped groove is 78 mm, a side length of an outer ring thereof is 82 mm, a groove width thereof is 2 mm, and a groove depth thereof is 6 mm.

The ring-shaped groove 324 may be directly processed on the second surface 321 of the light-transmitting pressing plate 320, and meanwhile, the vent hole 327 in communication with the ring-shaped groove 324 may be arranged on the contour surface 326 of the light-transmitting pressing plate 320 to obtain the first gas extraction port 322.

In some other embodiments, as shown in FIG. 9, the outer contour of the light-transmitting pressing plate 320 is rectangular; the light-transmitting pressing plate 320 includes four sub-contour surfaces 3261 between the first surface and the second surface 321. The first gas passage includes four gas channels 328 and four groups of ventilation holes 325. The four sub-contour surfaces 3261, the four gas channels 328, and the four groups of ventilation holes 325 are in one-to-one correspondence. One gas channel 328 is located between one corresponding sub-contour surface 3261 and the light-transmitting region AA. One end of one group of ventilation holes 325 is in communication with one corresponding gas channel 328, and the other end thereof is located on the second surface 321, forming the first adsorption port 323. One gas channel 328 extends to two sub-contour surfaces 3261 adjacent to one corresponding sub-contour surface 3261, and a pair of mouths are formed on the adjacent two sub-contour surfaces 3261. At least one mouth of four pairs of mouths forms the first gas extraction port 322 and is used to be in communication with the gas extraction device, while the remaining mouths are sealed.

In this way, since the first adsorption port 323 is formed by a plurality of groups of ventilation holes 325, a situation where the entire first adsorption port 323 is depressurized due to partial depressurization of some ventilation holes 325 when the light-transmitting pressing plate 320 adsorbs the first substrate is avoided, thereby improving the stability of adsorption of the first substrate.

Optionally, the four gas channels 328 are located in the same plane and are in communication with each other. In this case, one mouth of the four pairs of mouths may form the first gas extraction port 322, while remaining the other mouths sealed. In this way, the number of first gas extraction ports 322 may be reduced, and hence the number of gas extraction devices may be reduced. Each gas channel 328 extends in a straight-line direction and is parallel to a plane where one corresponding sub-contour surface 3261 is located.

A mouth shape of the ventilation hole 325 may be square, rectangular, circular, elliptical, etc. Exemplarily, if the light-transmitting region AA is rectangular, the mouth shape of the ventilation hole 325 may be set to be elliptical, and a long axis of the ellipse is parallel to a side edge close to the light-transmitting region AA. In this way, the size of the light-transmitting pressing plate 320 may be reduced while ensuring the adsorption strength of each ventilation hole 325 to the first substrate.

Optionally, a mouth area of the ventilation hole 325 is greater than or equal to 0.785 mm² and less than or equal to 7.065 mm². Exemplarily, the mouth area of the ventilation hole 325 is 0.785 mm², 0.1 mm², 1 mm², 3 mm², 5 mm², 7.065 mm², etc.

Based on the above, the effective adsorption area of the first adsorption port 323 on the second surface 321 of the light-transmitting pressing plate 320 is greater than 1.25 cm². At this time, the number of ventilation holes 325 on the second surface 321 of the light-transmitting pressing plate 320 may be determined according to a minimum effective adsorption area and the mouth area of the ventilation hole 325. Exemplarily, when an mouth diameter of the ventilation hole 325 is 1 mm, the mouth area is 3.14 mm², and hence the number of ventilation holes 325 is determined to be at least 40.

Optionally, a distance between two adjacent ventilation holes 325 (a distance between center points of the ventilation holes 325) is greater than or equal to 3 mm, which may ensure the structural strength of the light-transmitting pressing plate 320 after the ventilation holes 325 are arranged on the second surface 321 of the light-transmitting pressing plate 320, and may avoid a situation where the light-transmitting pressing plate 320 is prone to compression due to an excessively small distance between two adjacent ventilation holes 325. Exemplarily, the distance between two adjacent ventilation holes 325 is 3 mm, 4 mm, 5 mm, etc.

Further, the distance between two adjacent ventilation holes 325 is less than or equal to 6 mm, which ensures that a large number of ventilation holes 325 may be arranged on the second surface 321 of the light-transmitting pressing plate 320 to guarantee a sufficient effective adsorption area on the second surface 321 of the light-transmitting pressing plate 320. For example, the distance between two adjacent ventilation holes 325 is 4 mm, in which case the second surface 321 of the light-transmitting pressing plate 320 has 76 ventilation holes 325 to ensure the stable absorption of the first substrate by the light-transmitting pressing plate 320.

In a specific embodiment, as shown in FIG. 14, the light-transmitting pressing plate 320 is a cube with a side length of 100 mm (a thickness of 10 mm), and the mouth diameter of the ventilation hole on the second surface 321 of the light-transmitting pressing plate 320 is 1 mm (i.e., the mouth area is 3.14 mm²), with a distance of 4 mm between two adjacent ventilation holes 325. In addition, the light-transmitting pressing plate 320 also has eight stepped holes that are evenly distributed and penetrate the light-transmitting pressing plate, and each stepped hole has a diameter of 5.5 mm at a large diameter end and 2.9 mm at a small diameter end.

A plurality of ventilation holes 325 may be directly processed on the second surface 321 of the light-transmitting pressing plate 320, and meanwhile, gas channels 328 in communication with a row of ventilation holes 325 may be provided on the sub-contour surface 3261 of the light-transmitting pressing plate 320 along an arrangement direction of the plurality of ventilation holes 325, to obtain four gas channels 328 located on the four sub-contour surfaces and connected to each other. Then, one mouth of one gas channel 328 is reserved as the first gas extraction port 322, and mouths of the remaining gas channels 328 are sealed by sealing plugs.

The present disclosure provides a light-emitting chip transfer method, including:
transferring a light-emitting chip from a source substrate to an intermediate substrate, and then from the intermediate substrate to a display substrate,
wherein the light-emitting chip transfer apparatus described in the above embodiments is used to transfer the light-emitting chip from the source substrate to the intermediate substrate, in which the first substrate is the source substrate and the second substrate is the intermediate substrate; and/or the light-emitting chip transfer apparatus described in the above embodiments is used to transfer the light-emitting chip from the intermediate substrate to the display substrate, in which the first substrate is the intermediate substrate and the second substrate is the display substrate.

The present disclosure provides another light-emitting chip transfer method, including:
heating, pressurizing and laser-irradiating a first substrate and a second substrate located on a heating and pressurizing device by using the light-emitting chip transfer apparatus described in the above embodiments, wherein the first substrate allows a laser of a target wavelength to be transmitted in a first direction, and a light-emitting chip is initially located on the first substrate,
wherein a driving mechanism drives a pressurizing assembly to move and pressurize in a direction towards a carrying platform, so that the first substrate and the second substrate come into contact and generate interaction force; a heating member heats the second substrate carried on the carrying platform; laser generated by a laser irradiation device passes through a light-transmitting region of a light-transmitting pressing plate to laser-irradiate the first substrate and the second substrate, and the light-emitting chip on the first substrate is transferred to the second substrate.

In a specific embodiment, the light-emitting chip is located on one side of the first substrate, and a first adhesive layer exists between the first substrate and the light-emitting chip and is sensitive to laser of a specific wavelength (i.e., a dissociating adhesive that may be peeled off or dissociated by the laser of the specific wavelength). During the transfer of the light-emitting chip, the second substrate is arranged opposite to the first substrate, and one side of the second substrate facing the first substrate includes a second adhesive layer that is sensitive to a specific temperature (i.e., an adhesive layer that is glued after being heated to a certain temperature). After the first substrate comes into contact with the second substrate and generates the interaction force, when the laser sequentially passes through the light-transmitting pressing plate and the first substrate and acts on the first adhesive layer at a target position, the viscosity of the first adhesive weakens, making it easier for the light-emitting chip at the target position to adhere by the second adhesive layer, so as to achieve the transfer of the light-emitting chip from the first substrate to the second substrate. Heating, pressurization, and laser irradiation are carried out simultaneously, which is beneficial for firm adhesive of the transferred light-emitting chip with the second substrate.

For example, the laser may perform area irradiation (with a relatively large irradiation area) on the first substrate to transfer a plurality of light-emitting chips. For example, the laser may achieve point irradiation on the first substrate (which may be understood as that an irradiation area plays a transferring role for only one light-emitting chip), so as to transfer the light-emitting chip at one target position. For example, the laser may scan the first substrate to sequentially transfer a plurality of light-emitting chips arranged in an array from the first substrate to the second substrate. Therefore, the light-emitting chip transfer apparatus according to the present disclosure may realize selective transfer of the light-emitting chips.

It should be noted that, although the various steps of the method of the present disclosure are described in a particular order in the figures, it is not required or implied that the steps must be performed in the particular order, or all the illustrated steps must be performed to achieve the desired result. Additionally or alternatively, some steps may be omitted, or multiple steps may be combined into one step to be performed, and/or one step is decomposed into multiple steps to be performed, all of which should be regarded as part of the present disclosure.

It should be understood that application of the present disclosure is not limited to the detailed structure and arrangement of components provided in the present specification. The present disclosure may have other embodiments, and may be implemented and carried out in various ways. The foregoing variations and modifications fall within the scope of the present disclosure. It should be understood that the present disclosure disclosed and defined in this specification may extend to all alternative combinations of two or more of the individual features that are mentioned or apparent from the text and/or drawings. All of these different combinations form various alternative aspects of the present disclosure. The embodiments described herein explain the best modes known for carrying out the present disclosure, and will allow those skilled in the art to utilize the present disclosure.

1. A light-transmitting pressing plate, comprising a first surface and a second surface parallel to each other, each of the first surface and the second surface extending along a plane, and the light-transmitting pressing plate allowing a laser of a target wavelength to be transmitted in a first direction from the first surface to the second surface,
wherein the light-transmitting pressing plate is configured to transfer a light-emitting chip arranged on a first substrate to a second substrate under action of pressure and under action of the laser of the target wavelength; the first substrate is on one side of the light-transmitting pressing plate close to the second surface and allows the laser of the target wavelength to be transmitted in the first direction; the first substrate and the second substrate are on a same side of the light-transmitting pressing plate, and the first substrate is closer to the light-transmitting pressing plate than the second substrate.

2. The light-transmitting pressing plate according to claim 1, wherein a refractive index of the light-transmitting pressing plate for a laser with a wavelength of 355 nm is greater than 1 and less than 1.6.

3. The light-transmitting pressing plate according to claim 2, wherein a distance between the first surface and the second surface is greater than or equal to 8 mm and less than or equal to 35 mm.

4. The light-transmitting pressing plate according to claim 2, wherein an offset of a light spot is less than or equal to 0.5 mm after the light-transmitting pressing plate transmits a laser with an incident angle in a range of less than or equal to 14 degrees.

5. The light-transmitting pressing plate according to claim 2, wherein degradation of uniformity of a laser light spot does not exceed 2% after the light-transmitting pressing plate transmits laser within an A mm×B mm laser field, wherein A and B are both less than or equal to 70.

6. The light-transmitting pressing plate according to claim 2, wherein uniformity of a laser light spot, after the light-transmitting pressing plate transmits a laser with an incident angle in a range of less than or equal to 14 degrees, is equivalent to or superior to uniformity of the laser light spot before incidence.

7. The light-transmitting pressing plate according to claim 1, wherein a material of the light-transmitting pressing plate is a quartz glass.

8-22. (canceled)

23. The light-transmitting pressing plate according to claim 2, wherein a material of the light-transmitting pressing plate is a quartz glass.

24. The light-transmitting pressing plate according to claim 7, wherein the quartz glass internally contains a content, and a particle size of the content is less than 0.1 mm.

25. The light-transmitting pressing plate according to claim 1, comprising a light-transmitting region and a peripheral region, the peripheral region surrounding the light-transmitting region,
wherein a first gas passage is provided in the peripheral region, and the first gas passage has a first adsorption port extending to the second surface and distributed around the light-transmitting region.

26. The light-transmitting pressing plate according to claim 24, wherein the light-transmitting pressing plate comprises a contour surface between the first surface and the second surface;
the first gas passage comprises a ring-shaped groove and a vent hole; an opening of the ring-shaped groove is on the second surface and forms the first adsorption port; one end of the vent hole is in communication with the ring-shaped groove, and another end of the vent hole is in the contour surface and forms a first gas extraction port; the first gas extraction port is configured to be in communication with a gas extraction device.

27. The light-transmitting pressing plate according to claim 25, wherein an outer contour of the light-transmitting pressing plate is rectangular;
the light-transmitting pressing plate comprises four sub-contour surfaces between the first surface and the second surface, and the first gas passage comprises four gas channels and four groups of ventilation holes, the four sub-contour surfaces, the four gas channels, and the four groups of ventilation holes being in one-to-one correspondence;
one gas channel of the four gas channels is located between one corresponding sub-contour surface of the four sub-contour surfaces and the light-transmitting region, and one end of one group of ventilation holes of the four groups of ventilation holes is in communication with one corresponding gas channel of the four gas channels, while the other end of one group of ventilation holes of the four groups of ventilation holes is located in the second surface and forms the first adsorption port;
one gas channel of the four gas channels extends to two sub-contour surfaces adjacent to one corresponding sub-contour surface of the four sub-contour surfaces, and a pair of mouths are formed on the adjacent two sub-contour surfaces of the four sub-contour surfaces; at least one mouth of four pairs of mouths forms a first gas extraction port and is configured to be in communication with a gas extraction device, while remaining mouths of the four pairs of mouths are sealed.

28. The light-transmitting pressing plate according to claim 27, wherein the four gas channels are in communication with each other, and one mouth of the four pairs of mouths forms the first gas extraction port.

29. A pressurizing assembly, comprising a connecting portion and the light-transmitting pressing plate according to claim 1,
wherein the connecting portion has a through hollow region, and the connecting portion is fixedly connected to the light-transmitting pressing plate and is located on one side close to the first surface of the light-transmitting pressing plate;
in the first direction, there is an overlapping region between a light-transmitting region of the light-transmitting pressing plate and the hollow region.

30. The pressurizing assembly according to claim 29, further comprising a metal frame and an elastic pad that are located between the connecting portion and the light-transmitting pressing plate,
wherein the metal frame is located between the elastic pad and the light-transmitting pressing plate; each of the metal frame and the elastic pad has a ring-shaped structure; orthographic projections of the metal frame and the elastic pad on the light-transmitting pressing plate surround the light-transmitting region.

31. A heating and pressurizing device, comprising a heating carrying mechanism and a pressurizing driving mechanism,
wherein the heating carrying mechanism comprises a heating member and a carrying platform, the carrying platform is configured to carry a second substrate, and the heating member is configured to heat the second substrate on the carrying platform;
the pressurizing driving mechanism comprises a driving mechanism and the pressurizing assembly according to claim 29, the driving mechanism being connected to the pressurizing assembly;
the light-transmitting pressing plate and the carrying platform are arranged opposite to each other in the first direction; the light-transmitting pressing plate is configured to connect a first substrate; and the driving mechanism is configured to drive the light-transmitting pressing plate to move in the first direction, to allow the light-transmitting pressing plate to bring the first substrate into contact with the second substrate in the first direction and generate an interaction force.

32. The heating and pressurizing device according to claim 31, wherein the driving mechanism comprises:
a first slide rail extending along the first direction;
a slide head assembly slidably connected to the first slide rail, the slide head assembly being connected to the pressurizing assembly; and
a power driving member connected to the slide head assembly and configured to drive the slide head assembly to slide along the first slide rail and apply force to the pressurizing assembly.

33. The heating and pressurizing device according to claim 31, wherein a second gas passage is provided inside the carrying platform, and the second gas passage has a second adsorption port extending to a surface of the carrying platform facing one side of the pressurizing assembly.

34. The heating and pressurizing device according to claim 31, wherein there are two pressurizing driving mechanisms; the two pressurizing driving mechanisms are respectively located on both sides of the heating member in a second direction; the two pressurizing driving mechanisms are symmetrically arranged about a central axis of the heating member; and the second direction is perpendicular to the first direction.

35. The heating and pressurizing device according to claim 31, wherein a target wavelength is greater than or equal to 100 nm and less than or equal to 2000 nm.
